(19) United States
(12) Patent Application Publication
(10) Pub. No.: US 2026/0312561 A1
(43) Pub. Date: Oct. 8, 2026

(54) FILTER, PREPARATION METHOD THEREOF, AND ELECTRONIC APPARATUS

(71) Applicants: BEIJING BOE SENSOR TECHNOLOGY CO., LTD., Beijing (CN); BOE TECHNOLOGY GROUP CO., LTD., Beijing (CN); BEIJING BOE TECHNOLOGY DEVELOPMENT CO., LTD., Beijing (CN)

(72) Inventors: Huiying LI, Beijing (CN); Yue LI, Beijing (CN); Yuelei XIAO, Beijing (CN); Yifan WU, Beijing (CN); Qichang AN, Beijing (CN); Yingying ZHAO, Beijing (CN); Can ZHANG, Beijing (CN); Shuang XU, Beijing (CN); Biqi LI, Beijing (CN); Kuili REN, Beijing (CN)

(21) Appl. No.: 18/996,719

(22) PCT Filed: May 15, 2024
(86) PCT No.: PCT/CN2024/093293

§ 371 Date: Jan. 17, 2025

(30) Foreign Application Priority Data
Jun. 25, 2023 (CN) 202310754508.X

(51) Int. Cl. H03H 7/01; H01F 27/28; H01F 41/04; H01G 4/30

(52) U.S. Cl. CPC H03H 7/0115; H01F 27/2804; H01F 41/041; H01G 4/30; H01F 2017/0026; H01F 27/2809

(57) ABSTRACT

A filter includes a dielectric substrate having at least one capacitor and at least one inductor disposed thereon. The capacitor includes a first plate and a second plate opposite to each other, and the first plate is located on a side of the second plate close to the dielectric substrate; and at least one of the first plate or the second plate is electrically connected to the inductor. The inductor includes multiple layers of coil structures which are sequentially arranged on the dielectric substrate, and at least one first interlayer insulation layer is between adjacent coil structures; and the coil structures of adjacent layers are electrically connected together through a first connection via running through the first interlayer insulation layer between the coil structures. Orthographic projections of any two of the multiple layers of coil structures on the dielectric substrate partially overlap each other.

### TECHNICAL FIELD

The present disclosure belongs to the technical field of passive devices, and specifically relates to a filter, a preparation method thereof, and an electronic apparatus.

### BACKGROUND

Advances in the communication technology pose greater demands on the performance and size of electronic components. Passive devices such as capacitors, inductors and resistors on a printed circuit board (PCB) take an area of about 70% of the PCB. With the continuous emergence of new technologies, such as integrated product development (IPD), the area of passive devices can be reduced by more than 80%. The IPD technology effectively reduces the size of discrete components and component assembly wiring by integrating the most common passive devices in the electronic components.

As a vital part of the electronic component, the inductor may be used as a discrete device, or work as a part of circuitry, such as a common LC filter or a connecting wire in a package carrier. The conventional inductor takes a large area in the passive device due to a spiral structure, and therefore, miniaturization and performance optimization of the inductor are vital to development of the inductor.

### SUMMARY

To solve at least one of the technical problems in the existing art, the present disclosure provides a filter, a preparation method thereof, and an electronic apparatus.

In a first aspect, a technical solution adopted to solve the technical problem of the present disclosure is a filter, including a dielectric substrate having at least one capacitor and at least one inductor disposed thereon, wherein
the capacitor includes a first plate and a second plate opposite to each other, and the first plate is located on a side of the second plate close to the dielectric substrate; and at least one of the first plate or the second plate is electrically connected to the inductor; and
the inductor includes multiple layers of coil structures which are sequentially arranged on the dielectric substrate, and at least one first interlayer insulation layer is between adjacent coil structures; and the coil structures of adjacent layers are electrically connected together through a first connection via running through the first interlayer insulation layer between the coil structures; and
orthographic projections of any two of the multiple layers of coil structures on the dielectric substrate partially overlap each other.

In some embodiments, the capacitor is on a side of the inductor close to the dielectric substrate, and at least one second interlayer insulation layer is between the capacitor and the inductor.

In some embodiments, among the multiple layers of coil structures, a coil structure closest to the dielectric substrate is a first coil structure; and the second plate is electrically connected to the first coil structure.

In some embodiments, the capacitor further includes a first lead terminal, wherein
the first lead terminal and the second plate are in the same layer and integrally formed; and the first lead terminal is electrically connected to the first coil structure through a second connection via running through the second interlayer insulation layer between the second plate and the first coil structure.

In some embodiments, among the multiple layers of coil structures, a coil structure closest to the dielectric substrate is a first coil structure; and
the first plate and the first coil structure are in the same layer and electrically connected together.

In some embodiments, the first plate and the first coil structure are integrally formed.

In some embodiments, among the multiple layers of coil structures, a coil structure adjacent to the first coil structure is a second coil structure; and
a third interlayer insulation layer is between the second coil structure and the dielectric substrate, and covers the second plate, and the first plate and the first coil structure integrally formed.

In some embodiments, among the multiple layers of coil structures, a coil structure adjacent to the first coil structure is a second coil structure;
a fourth interlayer insulation layer and a fifth interlayer insulation layer are between the second coil structure and the dielectric substrate, wherein the fourth interlayer insulation layer is provided with a first receiving portion running through the fourth interlayer insulation layer in a thickness direction of the fourth interlayer insulation layer, the first plate and the first coil structure integrally formed are defined into the first receiving portion, and a surface of the first plate and the first coil structure integrally formed facing away from the dielectric substrate is flush with a surface of the fourth interlayer insulation layer facing away from the dielectric substrate; and
the fifth interlayer insulation layer is on a side of the fourth interlayer insulation layer facing away from the dielectric substrate, and covers the second plate.

In some embodiments, among the multiple layers of coil structures, a coil structure closest to the dielectric substrate is a first coil structure;
the first coil structure includes a first sub-coil and a second sub-coil arranged in a stack, and the first sub-coil is located on a side of the second sub-coil close to the dielectric substrate; and
the first plate and the first sub-coil are in the same layer and electrically connected together.

In some embodiments, the first plate and the first sub-coil are integrally formed.

In some embodiments, the filter further includes a connection structure, wherein the connection structure is on a side of the inductor facing away from the dielectric substrate, and electrically connected to a third coil structure in the inductor furthest from the dielectric substrate through a third connection via running through a sixth interlayer insulation layer between the connection structure and the third coil structure.

In some embodiments, the first interlayer insulation layer between any adjacent coil structures includes a first surface and a second surface opposite to each other in a thickness direction of the first interlayer insulation layer, and the first surface and the second surface are both parallel to a reference plane of the dielectric substrate extending in a first direction.

In some embodiments, a seventh interlayer insulation layer in the same layer as any of the coil structures includes a first surface and a second surface opposite to each other in a thickness direction of the seventh interlayer insulation layer, and the first surface and the second surface are both parallel to a reference plane of the dielectric substrate extending in a first direction.

In a second aspect, an embodiment of the present disclosure further provides a method for preparing a filter, including: providing a dielectric substrate, on which at least one capacitor and at least one inductor are formed; wherein forming the at least one capacitor and the at least one inductor includes:
forming a first conductive pattern on the dielectric substrate, wherein the first conductive pattern includes at least a first plate of the capacitor;
forming a second conductive pattern on a side of the first conductive pattern facing away from the dielectric substrate, wherein the second conductive pattern includes a second plate of the capacitor; and at least one of the second plate or the first plate is electrically connected to the inductor; and
forming multiple layers of third conductive patterns on a side of the second conductive pattern facing away from the dielectric substrate, and forming at least one first interlayer insulation layer between adjacent third conductive patterns, wherein the third conductive patterns include coil structures of the inductor, and the coil structures of adjacent layers are electrically connected together through a first connection via running through the first interlayer insulation layer between the coil structures; and orthographic projections of any two of the multiple layers of coil structures on the dielectric substrate partially overlap each other.

In some embodiments, forming the first conductive pattern on the dielectric substrate includes: forming a first conductive pattern including the first plate on the dielectric substrate; and
forming the multiple layers of third conductive patterns on the side of the second conductive pattern facing away from the dielectric substrate includes: forming multiple layers of coil structures on the side of the second conductive pattern facing away from the dielectric substrate, wherein among the multiple layers of coil structures, a coil structure closest to the dielectric substrate is a first coil structure; and the first coil structure is electrically connected to the second plate through a second connection via running through a second interlayer insulation layer between the first coil structure and the second plate.

In some embodiments, among the multiple layers of coil structures in the inductor, a coil structure closest to the dielectric substrate is a first coil structure; and
forming the first conductive pattern on the dielectric substrate includes:
forming a first conductive pattern including the first plate and the first coil structure on the dielectric substrate.

In some embodiments, the first plate and the first coil structure are integrally formed; wherein after forming the second conductive pattern, the method further includes:
forming a third interlayer insulation layer on a side of the second conductive pattern facing away from the first conductive pattern; wherein the third interlayer insulation layer covers the second plate, and the first plate and the first coil structure integrally formed.

In some embodiments, the first plate and the first coil structure are integrally formed;
forming the first conductive pattern including the first plate and the first coil structure on the dielectric substrate includes:
forming a fourth interlayer insulation layer on the dielectric substrate, wherein the fourth interlayer insulation layer includes a first receiving portion running through the fourth interlayer insulation layer in a thickness direction of the fourth interlayer insulation layer; and
filling the first plate and the first coil structure integrally formed in the first receiving portion to form the first conductive pattern, wherein a surface of the first plate and the first coil structure integrally formed facing away from the dielectric substrate is flush with a surface of the fourth interlayer insulation layer facing away from the dielectric substrate.

In some embodiments, after forming the second conductive pattern, the method further includes:
forming a fifth interlayer insulation layer on a side of the second conductive pattern facing away from the first conductive pattern, wherein a surface of the fifth interlayer insulation layer facing away from the dielectric substrate is parallel to a reference plane of the dielectric substrate extending in a first direction.

In some embodiments, forming any one layer of the third conductive patterns includes:
forming a seventh interlayer insulation layer on the dielectric substrate with the second conductive pattern, wherein the seventh interlayer insulation layer includes a second receiving portion running through the seventh interlayer insulation layer in a thickness direction of the seventh interlayer insulation layer; and
filling a coil structure material of the inductor in the second receiving portion to form the third conductive pattern, wherein a surface of the third conductive pattern facing away from the dielectric substrate is flush with a surface of the seventh interlayer insulation layer facing away from the dielectric substrate.

In some embodiments, forming any one layer of the third conductive patterns includes:
forming, through electroplating, the third conductive pattern including the coil structure on a side of the first interlayer insulation layer facing away from the dielectric substrate.

In some embodiments, the dielectric substrate includes a glass substrate.

In a third aspect, an embodiment of the present disclosure further provides an electronic apparatus, including the filter according to the first aspect.

### BRIEF DESCRIPTION OF DRAWINGS

FIG. 1 is a front view of a planar (2D) spiral inductor in the existing art;

FIG. 2 is a schematic diagram of a filter according to an embodiment of the present disclosure;

FIG. 3 is a front view of a filter according to an embodiment of the present disclosure;

FIG. 4 is a specific structural diagram of an exemplary filter according to an embodiment of the present disclosure;

FIG. 5 is a specific structural diagram of another exemplary filter according to an embodiment of the present disclosure;

FIG. 6 is a specific structural diagram of another exemplary filter according to an embodiment of the present disclosure;

FIG. 7 is a specific structural diagram of another exemplary filter according to an embodiment of the present disclosure;

FIG. 8 is a specific structural diagram of another exemplary filter according to an embodiment of the present disclosure;

FIGS. 9a to 9j are schematic diagrams illustrating preparation of the filter shown in FIG. 4 according to an embodiment of the present disclosure;

FIGS. 10a to 10h are schematic diagrams illustrating preparation of the filter shown in FIG. 5 according to an embodiment of the present disclosure;

FIGS. 11a to 11i are schematic diagrams illustrating preparation of the filter shown in FIG. 6 according to an embodiment of the present disclosure;

FIGS. 12a to 12h are schematic diagrams illustrating preparation of the filter shown in FIG. 7 according to an embodiment of the present disclosure; and

FIGS. 13a to 13k are schematic diagrams illustrating preparation of the filter shown in FIG. 8 according to an embodiment of the present disclosure.

Reference Characters: 1, dielectric substrate; X, first direction;
2, capacitor; 21, first plate; 22. second plate; 23, first lead terminal;
3, inductor; 31, first coil structure; 32, second coil structure; 33, third coil structure; O1, first connection terminal; O2, second connection terminal; 311, first sub-coil; 312, second sub-coil;
41, first interlayer insulation layer; 42, second interlayer insulation layer; 43, third interlayer insulation layer; 44, fourth interlayer insulation layer; 45, fifth interlayer insulation layer; 46, sixth interlayer insulation layer; 47, seventh interlayer insulation layer; 40, insulation layer; Via1, first connection via; Via2, second connection via; Via3, third connection via; 441, first receiving portion; 471, second receiving portion;
M1, first conductive pattern; M2, second conductive pattern; M3, third conductive pattern;
5, connection structure; 51, first connection sub-layer; 52, second connection sub-layer; and 53, barrier layer.

### DETAIL DESCRIPTION OF EMBODIMENTS

To clarify the objects, technical solutions and advantages of the embodiments of the present disclosure, the technical solutions in the embodiments of the present disclosure will be clearly and completely described below with reference to the accompanying drawings in the embodiments of the present disclosure. Obviously, the described embodiments are merely some, not all, of the embodiments of the present disclosure. The components in the embodiments of the present disclosure, as generally described and illustrated in the figures herein, could be arranged and designed in a wide variety of different configurations. Therefore, the following detailed description of the embodiments of the present disclosure, provided in the accompanying drawings, is not intended to limit the scope of the present disclosure as claimed, but is merely representative of selected embodiments of the present disclosure. All other embodiments, which can be derived by those skilled in the art from the embodiments of the present disclosure without making any creative effort, shall fall within the protection scope of the present disclosure.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprising” or “including” or the like means that the element or item preceding the word contains elements or items that appear after the word or equivalents thereof, but does not exclude other elements or items. The terms “connected” or “coupled” and the like are not restricted to physical or mechanical connection, but may include electrical connection, either direct or indirect. The words “upper”, “lower”, “left”, “right”, and the like are merely used to indicate a relative positional relationship, and when an absolute position of the described object is changed, the relative positional relationship may be changed accordingly.

Reference to “a plurality of or several” in the present disclosure means two or more. The term “and/or” describes an association relationship of associated objects, which may include three relationships; for example, A and/or B may refer to: A alone, A and B, or B alone. The character “/” generally indicates that the former and latter associated objects are in an “or” relationship.

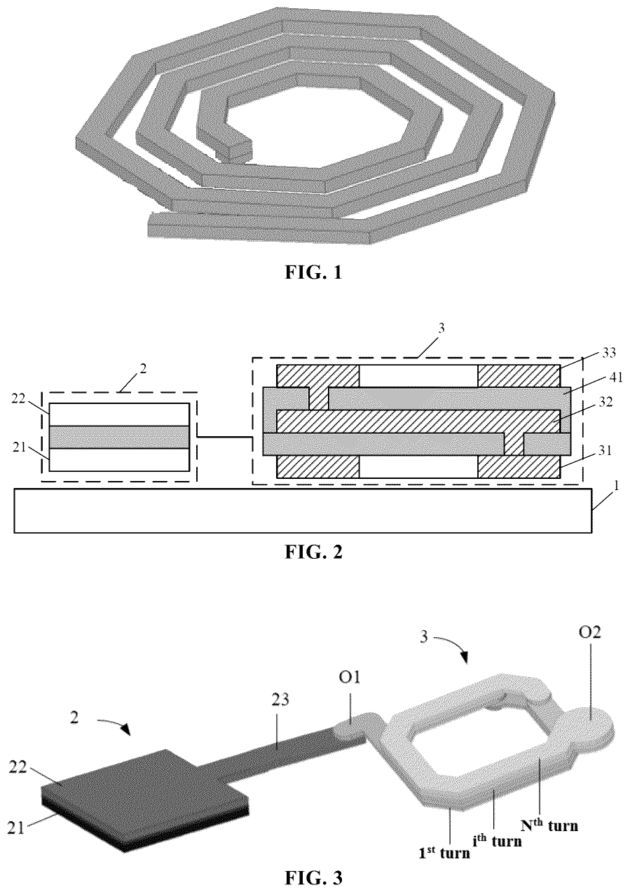

In the existing art, FIG. 1 is a front view of a planar (2D) spiral inductor in the existing art. As shown in FIG. 1, a current 2D integrated passive device (IPD) typically has a spiral inductor formed on a glass surface by a metal film layer. Since the inductor is made of the same metal layer, the inductor generally has a relatively large area, resulting a large area of the resulting device, which is not favorable for achieving a miniaturized device.

In view of this, an embodiment of the present disclosure provides a filter, which substantially eliminates one or more of the problems due to limitations and defects in the existing art. Specifically, the filter in the embodiment of the present disclosure includes a dielectric substrate having at least one capacitor and at least one inductor disposed thereon, wherein the capacitor includes a first plate and a second plate disposed opposite to each other, and the first plate is located on a side of the second plate close to the dielectric substrate; and at least one of the first plate or the second plate is electrically connected to the inductor; and the inductor includes multiple layers of coil structures which are sequentially arranged on the dielectric substrate, and at least one first interlayer insulation layer is disposed between adjacent coil structures; and the coil structures of adjacent layers are electrically connected together through a first connection via running through the first interlayer insulation layer between the coil structures; and orthographic projections of any two of the multiple layers of coil structures on the dielectric substrate partially overlap each other.

In the embodiment of the present disclosure, a three-dimensional spiral inductor (with multiple layers of coil structures) is formed and interconnected with a capacitor to form an LC-type filter. Since the orthographic projections of any two layers of coil structures in the three-dimensional spiral inductor on the dielectric substrate partially overlap each other, under the condition that the formed coil structure has the same number of turns, the present disclosure can reduce the overall area of the coils in an overlooking plane of the inductor and thereby save the space of the device compared with the existing art.

The following provides a detailed description of the specific structure of a filter according to an embodiment of the present disclosure.

FIG. 2 is a schematic diagram of a filter according to an embodiment of the present disclosure; and FIG. 3 is a front view of a filter according to an embodiment of the present disclosure. As shown in FIGS. 2 and 3, the filter includes a dielectric substrate 1 having at least one capacitor 2 and at least one inductor 3 disposed thereon. The capacitor 2 includes a first plate 21 and a second plate 22 disposed opposite to each other, and the first plate 21 is located on a side of the second plate 22 close to the dielectric substrate 1. At least one of the first plate 21 or the second plate 22 is electrically connected to the inductor 3. The inductor 3 includes multiple layers of coil structures which are sequentially arranged on the dielectric substrate 1, and at least one first interlayer insulation layer 41 is disposed between adjacent coil structures. The coil structures of adjacent layers are electrically connected together through a first connection via via1 running through the first interlayer insulation layer 41 between the coil structures. Orthographic projections of any two of the multiple layers of coil structures on the dielectric substrate 1 partially overlap each other.

Illustratively, as shown in FIG. 3, the multiple layers of coil structures include N layers; and the N layers of coil structures form a three-dimensional spiral structure of N turns, and different coil structures are located in different layers, where N≥2 and N is an integer. A tail end of an i^{th} turn of coil structure is electrically connected to a head end of an (n+1)^{th} turn of coil structure through a first connection via via1 running through the first interlayer insulation layer 41, where i is an integer less than or equal to N. The inductor 3 includes a first connection terminal O1 and a second connection terminal O2 electrically connected to other components, where the first connection terminal O1 is a head end of a first turn of coil structure (i.e., a first coil structure 31 described below), and the second connection terminal O2 is a tail end of an N^{th} turn of coil structure (i.e., a third coil structure 33 described below). The first turn of coil structure is a coil structure closest to the dielectric substrate 1 among the multiple layers of coil structures; and the N^{th} turn of coil structure is a coil structure furthest from the dielectric substrate 1 among the multiple layers of coil structures.

Illustratively, as shown in FIG. 3, orthographic projections of the respective coil structures in the multiple layers of coil structures on the dielectric substrate 1 partially overlap each other.

Referring to the above examples, by means of the coils arranged to be sequentially connected and having projections mostly overlapped, the overall area of the coils in an overlooking plane of the inductor 3 can be reduced, so that the wiring space for the device is saved, and the miniaturization design of the device is facilitated.

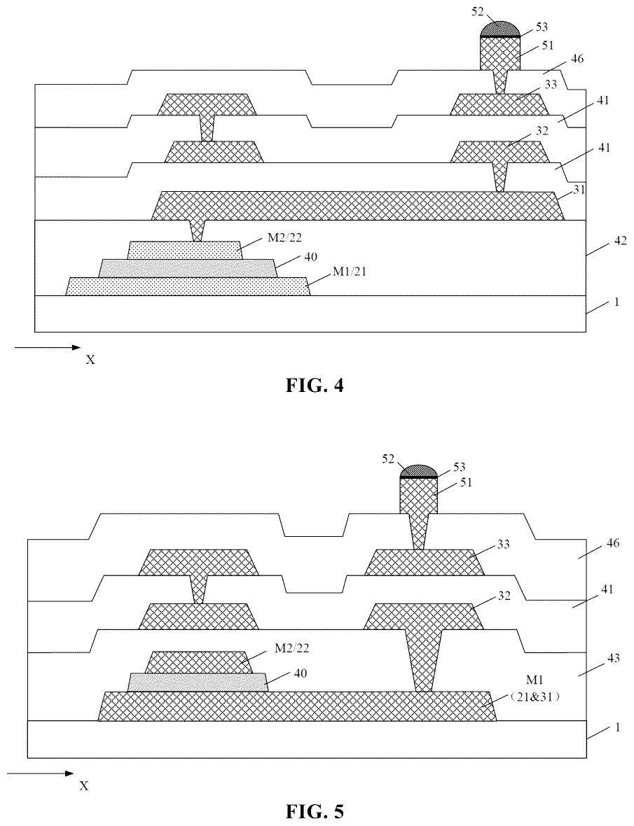

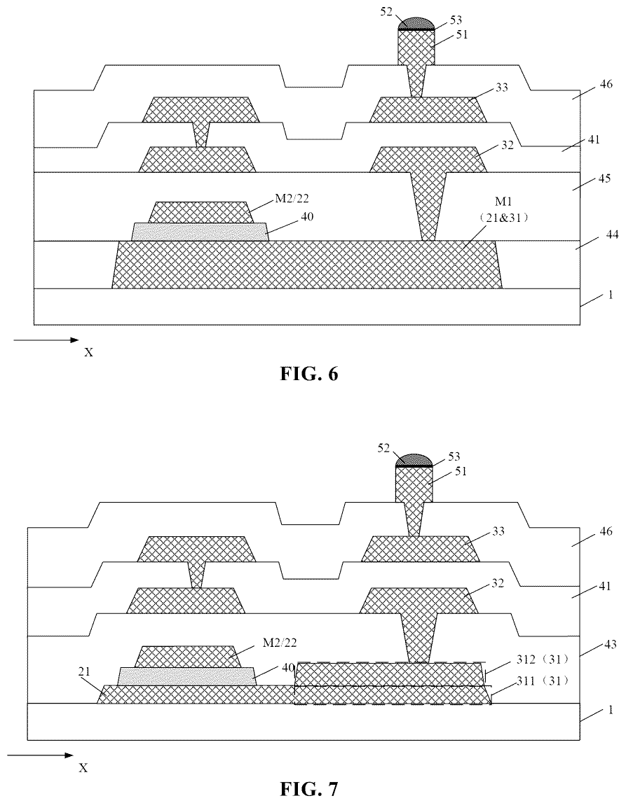

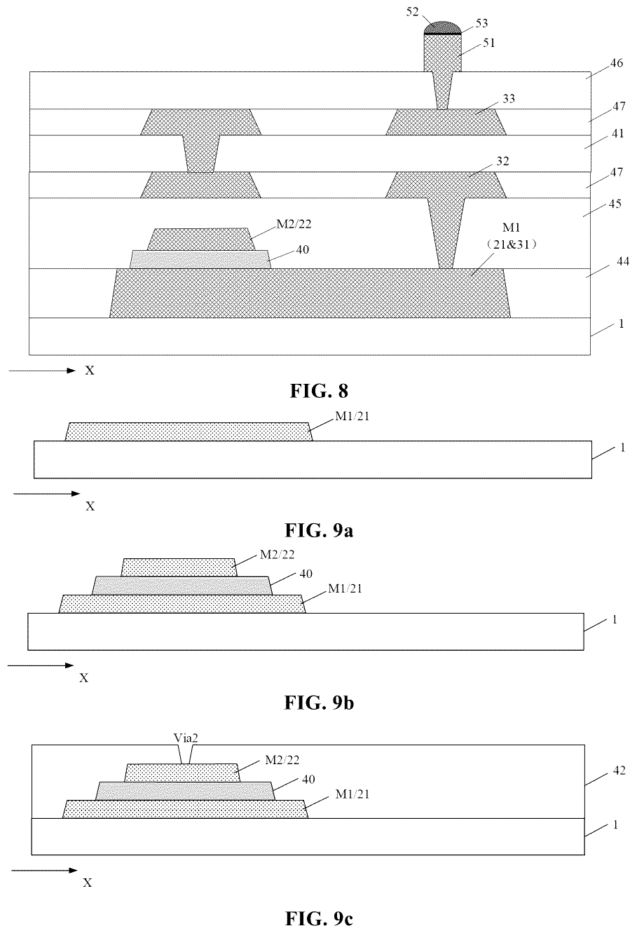

FIG. 4 is a specific structural diagram of an exemplary filter according to an embodiment of the present disclosure; FIG. 5 is a specific structural diagram of another exemplary filter according to an embodiment of the present disclosure; FIG. 6 is a specific structural diagram of another exemplary filter according to an embodiment of the present disclosure; FIG. 7 is a specific structural diagram of another exemplary filter according to an embodiment of the present disclosure; and FIG. 8 is a specific structural diagram of another exemplary filter according to an embodiment of the present disclosure.

In some embodiments, as shown in FIG. 4, the capacitor 2 is disposed on a side of the inductor 3 close to the dielectric substrate 1, and at least one second interlayer insulation layer 42 is disposed between the capacitor 2 and the inductor 3.

Illustratively, as shown in FIG. 4, one second interlayer insulation layer 42 is disposed between the capacitor 2 and the inductor 3, and covers the capacitor 2, that is, covers a first plate 21 and a second plate 22 in the capacitor 2, as well as an insulation layer 40 between the first plate 21 and the second plate 22.

The capacitor 2 disposed on the side of the inductor 3 close to the dielectric substrate 1 is merely taken as an example; and apparently, the capacitor 2 may be disposed on a side of the inductor 3 facing away from the dielectric substrate 1 instead, which is not specifically limited in the embodiments of the present disclosure.

To better clarify the structure of the filter provided in the embodiments of the present disclosure, the filter provided in the embodiments of the present disclosure is described below with reference to specific examples by taking the capacitor 2 disposed on the side of the inductor 3 close to the dielectric substrate 1 as an example.

First example: as shown in FIG. 4, among the multiple layers of coil structures, a coil structure closest to the dielectric substrate 1 is a first coil structure 31; and the second plate 22 is electrically connected to the first coil structure 31.

Illustratively, the second plate 22 may be electrically connected to the first coil structure 31 through a second connection via via2 running through the second interlayer insulation layer 42 between the first coil structure 31 and the second plate.

In a possible implementation, referring to FIG. 2, the capacitor 2 further includes a first lead terminal 23.

As shown in FIG. 4, the first lead terminal 23 and the second plate 22 are disposed in the same layer and integrally formed; and the first lead terminal 23 is electrically connected to the first coil structure 31 through a second connection via via2 running through the second interlayer insulation layer 42 between the second plate 22 and the first coil structure 31. Here, the first plate 21 and the second plate 22 of the capacitor 2 are disposed opposite to each other, and have orthographic projections on the dielectric substrate 1 which are completely overlapped with each other. The capacitor 2 is provided with a first lead terminal 23, through which the capacitor 2 is connected to the inductor 3, so that a coupling capacitor between the capacitor 2 and the inductor 3, which may affect the device, is avoided.

For the filter shown in FIG. 4, by means of the coils arranged to be sequentially connected together and having projections mostly overlapped with each other, the overall area of the coils in an overlooking plane of the inductor 3 can be reduced, so that the wiring space for the device is saved, and the miniaturization design of the device is facilitated.

Second example: As shown in FIG. 5, among the multiple layers of coil structures, a coil structure closest to the dielectric substrate 1 is a first coil structure 31; and the first plate 21 and the first coil structure 31 are disposed in the same layer and electrically connected together.

In a possible implementation, referring to FIG. 5, the first plate 21 and the first coil structure 31 are integrally formed. In this case, by means of the first plate 21 and the first coil structure 31 integrally formed, the number of process steps can be reduced, thereby reducing the production cost. In addition, by generating the first plate 21 and the first coil structure 31 integrally formed, an overall structural thickness of the inductor 3 can be effectively reduced, thereby facilitating a lightweight design of the device.

In a possible implementation, referring to FIG. 5, among the multiple layers of coil structures, a coil structure adjacent to the first coil structure 31 is a second coil structure 32. A third interlayer insulation layer 43 is disposed between the second coil structure 32 and the dielectric substrate 1, and covers the second plate 22, and the first plate 21 and the first coil structure 31 integrally formed.

In this case, by forming the third interlayer insulation layer 43 covering the second plate 22, and the first plate 21 and the first coil structure 31 integrally formed through one patterning process, the capacitor 2 and the first coil structure 31 can be insulated from the second coil structure 32 in an upper layer, thereby reducing the number of process steps and the production cost.

Third example: As shown in FIG. 6, among the multiple layers of coil structures, a coil structure closest to the dielectric substrate 1 is a first coil structure 31; and the first plate 21 and the first coil structure 31 are disposed in the same layer and electrically connected together.

In a possible implementation, referring to FIG. 6, the first plate 21 and the first coil structure 31 are integrally formed. In this case, by generating the first plate 21 and the first coil structure 31 integrally formed, the number of process steps can be reduced, thereby reducing the production cost. In addition, by generating the first plate 21 and the first coil structure 31 integrally formed, an overall structural thickness of the inductor 3 can be effectively reduced, thereby facilitating a lightweight design of the device.

Illustratively, the first plate 21 and the first coil structure 31 integrally formed may be specifically formed through an electroplating process on a seed layer; the seed layer may be made of a material selected from titanium (Ti), tantalum (Ta), titanium nitride (TiN), tantalum nitride (TaN) and the like; and the electroplating material may be made of a metal material selected from copper (Cu), gold (Au), aluminum (Al), silver (Ag) and the like.

In the present disclosure, by growing and forming the first plate 21 and the first coil structure 31 integrally formed, through electroplating on a seed layer, the metallic first plate 21 and first coil structure 31 integrally formed can be better bonded to the dielectric substrate 1.

In a possible implementation, referring to FIG. 6, among the multiple layers of coil structures, a coil structure adjacent to the first coil structure 31 is a second coil structure 32. A fourth interlayer insulation layer 44 and a fifth interlayer insulation layer 45 are disposed between the second coil structure 32 and the dielectric substrate 1. The fourth interlayer insulation layer 44 is provided with a first receiving portion 441 running through the fourth interlayer insulation layer in a thickness direction of the fourth interlayer insulation layer, into which the first plate 21 and the first coil structure 31 integrally formed are defined, and a surface of the first plate 21 and the first coil structure 31 integrally formed facing away from the dielectric substrate 1 is flush with a surface of the fourth interlayer insulation layer 44 facing away from the dielectric substrate 1. The fifth interlayer insulation layer 45 is disposed on a side of the fourth interlayer insulation layer 44 facing away from the dielectric substrate 1, and covers the second plate 22.

In this case, by providing the surface of the fourth interlayer insulation layer 44 facing away from the dielectric substrate 1 flush with the surface of the first plate 21 and the first coil structure 31 integrally formed facing away from the dielectric substrate 1, opposite surfaces of the fifth interlayer insulation layer 45 disposed above the fourth interlayer insulation layer 44, in the thickness direction of the fifth interlayer insulation layer 45, are parallel to a reference plane of the dielectric substrate 1 extending in a first direction X, so that the undulation degree of some film layers can be reduced, and even further, an interlayer insulation layer surface without undulation can be formed, which can help to achieve a more uniform thickness at different positions of some film layers and thus more uniform performance of the device.

Fourth example: As shown in FIG. 7, among the multiple layers of coil structures, a coil structure closest to the dielectric substrate 1 is a first coil structure 31; the first coil structure 31 includes a first sub-coil 311 and a second sub-coil 312 arranged in a stack, and the first sub-coil 311 is located on a side of the second sub-coil 312 close to the dielectric substrate 1; and the first plate 21 and the first sub-coil 311 are disposed in the same layer and electrically connected together.

Illustratively, no other structure is provided between the first sub-coil 311 and the second sub-coil 312 arranged in a stack. In other words, the second sub-coil 312 is disposed on a surface of the first sub-coil 311 facing away from the dielectric substrate 1, and the two sub-coils are seamlessly connected together.

Illustratively, the first sub-coil 311 and the second sub-coil 312 may be integrally formed.

Illustratively, the first sub-coil 311 may be a seed layer of the second sub-coil 312. The second sub-coil 312 is formed on the seed layer through an electroplating process, and the second sub-coil 312 may be made of a metal material selected from copper (Cu), gold (Au), aluminum (Al), and silver (Ag). In this case, the second sub-coil 312 can be better bonded to the dielectric substrate 1.

In a possible implementation, referring to FIG. 7, the first plate 21 and the first sub-coil 311 are integrally formed. In this case, by means of the first plate 21 and the first sub-coil 311 integrally formed, the number of process steps can be reduced, thereby reducing the production cost. In addition, by generating the first plate 21 and the first sub-coil 311 integrally formed, an overall structural thickness of the inductor 3 can be effectively reduced, thereby facilitating a lightweight design of the device.

Illustratively, the first plate 21 and the first sub-coil 311 integrally formed may be selected to be made of titanium (Ti) which has better adhesion, so that the metallic first plate 21 and first sub-coil 311 can be better bonded to the dielectric substrate 1.

Fifth example: As shown in FIG. 8, among the multiple layers of coil structures, a coil structure closest to the dielectric substrate 1 is a first coil structure 31; and the first plate 21 and the first coil structure 31 are disposed in the same layer and electrically connected together.

In a possible implementation, referring to FIG. 8, the first plate 21 and the first coil structure 31 are integrally formed. In this case, by generating the first plate 21 and the first coil structure 31 integrally formed, the number of process steps can be reduced, thereby reducing the production cost. In addition, by generating the first plate 21 and the first coil structure 31 integrally formed, an overall structural thickness of the inductor 3 can be effectively reduced, thereby facilitating a lightweight design of the device.

Illustratively, the first plate 21 and the first coil structure 31 integrally formed may be specifically formed through an electroplating process on a seed layer; the seed layer may be made of a material selected from titanium (Ti), tantalum (Ta), titanium nitride (TiN), tantalum nitride (TaN) and the like; and the electroplating material may be made of a metal material selected from copper (Cu), gold (Au), aluminum (Al), silver (Ag) and the like.

In the embodiment of the present disclosure, the first plate 21 and the first coil structure 31 integrally formed may be selected to be made of titanium (Ti) which has better adhesion, so that the metallic first plate 21 and first coil structure 31 can be better bonded to the dielectric substrate 1.

In a possible implementation, referring to FIG. 8, among the multiple layers of coil structures, a coil structure adjacent to the first coil structure 31 is a second coil structure 32. A fourth interlayer insulation layer 44 and a fifth interlayer insulation layer 45 are disposed between the second coil structure 32 and the dielectric substrate 1. The fourth interlayer insulation layer 44 is provided with a first receiving portion 441 running through the fourth interlayer insulation layer in a thickness direction of the fourth interlayer insulation layer, into which the first plate 21 and the first coil structure 31 integrally formed are defined, and a surface of the first plate 21 and the first coil structure 31 integrally formed facing away from the dielectric substrate 1 is flush with a surface of the fourth interlayer insulation layer 44 facing away from the dielectric substrate 1. The fifth interlayer insulation layer 45 is disposed on a side of the fourth interlayer insulation layer 44 facing away from the dielectric substrate 1, and covers the second plate 22.

As further shown in FIG. 8, the first interlayer insulation layer 41 between any adjacent coil structures includes a first surface and a second surface disposed opposite to each other in a thickness direction of the first interlayer insulation layer, and the first surface and the second surface are both parallel to a reference plane of the dielectric substrate 1 extending in a first direction X.

As further shown in FIG. 8, a seventh interlayer insulation layer 47 in the same layer as any of the coil structures includes a first surface and a second surface disposed opposite to each other in a thickness direction of the seventh interlayer insulation layer, and the first surface and the second surface are both parallel to a reference plane of the dielectric substrate 1 extending in a first direction X.

Referring to the above implementations, in the filter shown in FIG. 8, the undulation degree of some film layers is reduced, and an interlayer insulation layer surface without undulation is formed, which can help to achieve a more uniform thickness at different positions of each film layer and thus more uniform performance of the device.

The above examples provide structural description of the corresponding types of filters.

In some embodiments, a planarized film layer structure may be provided for each type of filter. Specifically, the first interlayer insulation layer 41 between any adjacent coil structures includes a first surface and a second surface disposed opposite to each other in a thickness direction of the first interlayer insulation layer, and the first surface and the second surface are both parallel to a reference plane of the dielectric substrate 1 extending in a first direction X, which can help to achieve a more uniform thickness at different positions of the first interlayer insulation layer 41 and thus more uniform performance of the device.

In some embodiments, a planarized film layer structure may be provided for each type of filter. Specifically, a seventh interlayer insulation layer 47 in the same layer as any of the coil structures includes a first surface and a second surface disposed opposite to each other in a thickness direction of the seventh interlayer insulation layer, and the first surface and the second surface are both parallel to a reference plane of the dielectric substrate 1 extending in a first direction X, which can help to achieve a more uniform thickness at different positions of the seventh interlayer insulation layer 47 in the same layer as the coil structure and the coil structure, and thus helps to achieve more uniform performance of the device.

In some embodiments, as shown in FIGS. 4 to 8, the filter further includes a connection structure 5. The connection structure 5 is disposed on a side of the inductor 3 facing away from the dielectric substrate 1, and electrically connected to a third coil structure 33 in the inductor 3 furthest from the dielectric substrate 1 through a third connection via via3 running through a sixth interlayer insulation layer 46 between the connection structure 5 and the third coil structure 33.

Illustratively, the connection structures 5 may be a copper pillar or a solder ball. The connection structure 5 may serve as a lead out terminal for the inductor 3.

Illustratively, the connection structure 5 may include a first connection sub-layer 51, and a second connection sub-layer 52 on a side of the first connection sub-layer 51 facing away from the dielectric substrate 1. The first connection sub-layer 51 may be made of a metal material such as copper (Cu), gold (Au), aluminum (Al), or silver (Ag), and the second connection sub-layer 52 may be made of a material such as silver-tin alloy (Sn—Ag) or tin (Sn). In the embodiments of the present disclosure, the case where the first connection sub-layer 51 is made of copper (Cu), and the second connection sub-layer 52 is made of a Sn—Ag alloy is taken as an example for illustration.

Illustratively, the connection structure 5 may further include a barrier layer 53 between the first connection sub-layer 51 and the second connection sub-layer 52. The barrier layer 53 may be selected to be made of nickel (Ni), so as to prevent Sn in the second connection sub-layer 52 from penetrating into the first connection sub-layer 51.

Illustratively, the sixth insulation layer includes a first surface and a second surface disposed opposite to each other in a thickness direction of the sixth interlayer insulation layer, and the first surface and the second surface are both parallel to a reference plane of the dielectric substrate 1 extending in a first direction X, which can help to achieve a more uniform thickness of the sixth interlayer insulation layer 46 and thus more uniform performance of the entire device.

In some embodiments, the dielectric substrate 1 may be selected to be made of glass, high-resistivity silicon, ceramic, or any other high-insulating and low-dielectric-loss material. Preferably, the dielectric substrate 1 is selected to be made of glass, which has a high dielectric constant and lower dielectric loss.

In addition, an embodiment the present disclosure further provides a method for preparing a filter, which may be used to prepare any one of the filters described above. The method includes: providing a dielectric substrate 1, on which at least one capacitor 2 and at least one inductor 3 are formed. Forming the at least one capacitor 2 and the at least one inductor 3 includes the following steps S11 to S13.

At S11, forming a first conductive pattern M1 on the dielectric substrate 1.

The first conductive pattern M1 includes at least a first plate 21 of the capacitor 2.

Illustratively, for the filter in the first example, the first conductive pattern M1 includes only the first plate 21; while for the filters in the second to fifth examples, the first conductive pattern M1 includes the first plate 21 and a first coil structure 31 of the inductor 3.

At S12, forming a second conductive pattern M2 on a side of the first conductive pattern M1 facing away from the dielectric substrate 1.

The second conductive pattern M2 includes a second plate 22 of the capacitor 2; and at least one of the second plate 22 or the first plate 21 is electrically connected to the inductor 3.

After the first conductive pattern M1 is formed, an insulation layer 40 is formed on a side of the first plate 21 facing away from the dielectric substrate 1 to isolate the second plate 22. Therefore, forming the second plate 22 includes: forming a second conductive pattern M2 including the second plate 22 on a side of the insulation layer 40 facing away from the dielectric substrate 1.

At S13, forming multiple layers of third conductive patterns M3 on a side of the second conductive pattern M2 facing away from the dielectric substrate 1, and forming at least one first interlayer insulation layer 41 between adjacent third conductive patterns M3.

The third conductive patterns M3 include coil structures of the inductor 3, and the coil structures of adjacent layers are electrically connected together through a first connection via via1 running through the first interlayer insulation layer 41 between the coil structures. Orthographic projections of any two of the multiple layers of coil structures on the dielectric substrate 1 partially overlap each other.

In the embodiment of the present disclosure, a three-dimensional spiral inductor 3 (with multiple layers of coil structures) is formed and interconnected with a capacitor 2 to form an LC-type filter. Since the orthographic projections of any two layers of coil structures in the three-dimensional spiral inductor 3 on the dielectric substrate 1 partially overlap each other, under the condition that the formed coil structure has the same number of turns, the present disclosure can reduce the overall area of the coils in an overlooking plane of the inductor 3 and thereby save the space of the device compared with the existing art.

To make the method for preparing the filter according to the embodiment of the present disclosure clearer, the following describes the methods for preparing the filters in different examples, respectively.

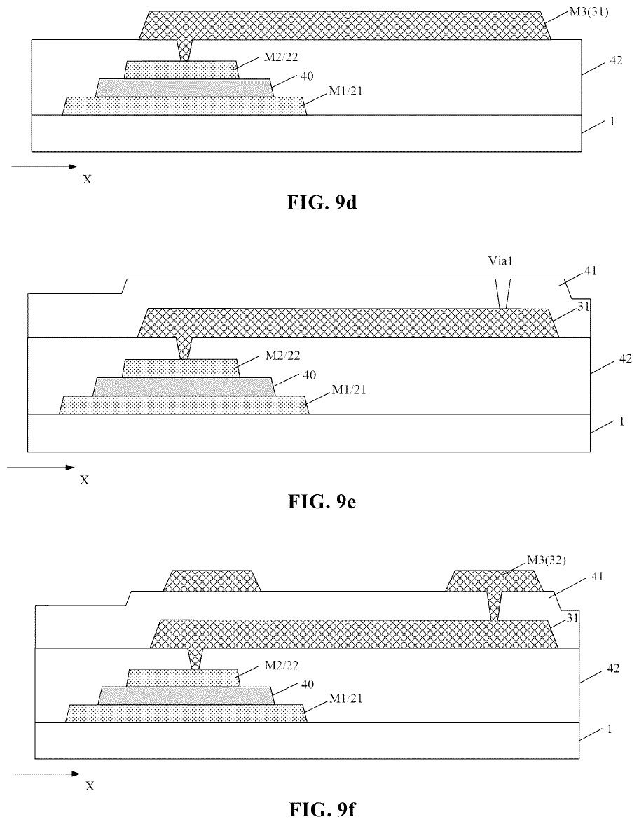

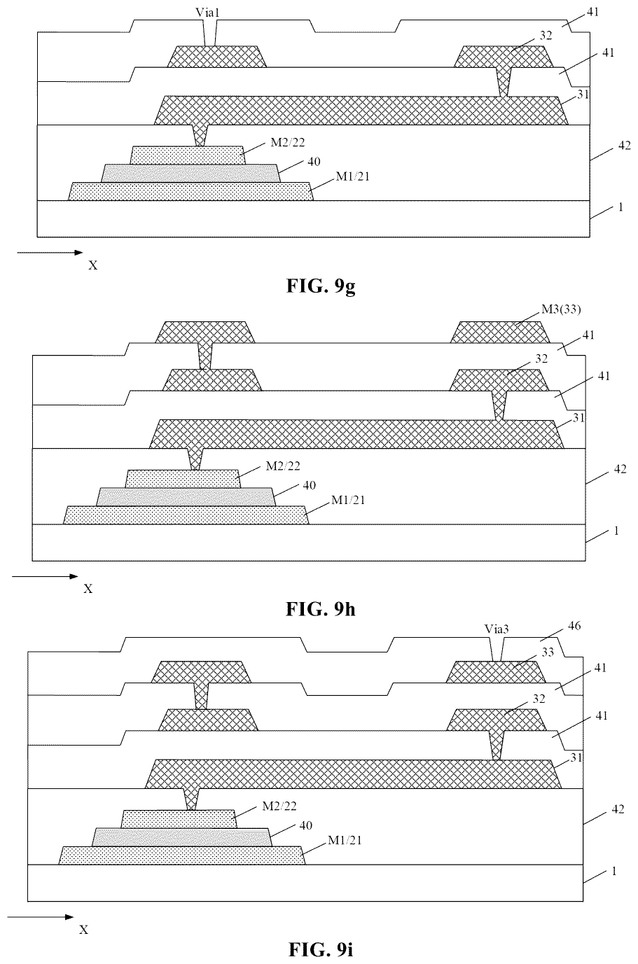

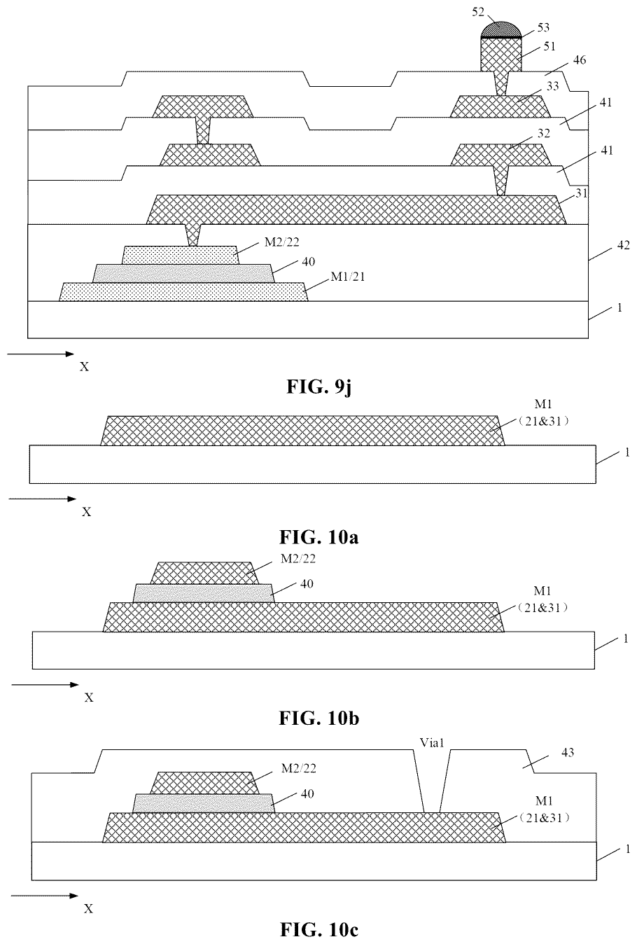

In some embodiments, FIGS. 9a to 9j are schematic diagrams illustrating preparation of the filter shown in FIG. 4 according to an embodiment of the present disclosure. As shown in FIGS. 9a to 9j, the method includes the following steps S21 to S27:

At S21, providing a dielectric substrate 1.

Illustratively, a dielectric substrate 1, with a thickness of 0.15 mm to 2 mm and applicable to mass production, is prepared according to the requirements of process equipment, where the dielectric substrate 1 may be selected to be made of glass, high-resistivity silicon, ceramic, or any other high-insulating and low-dielectric-loss material. Step S21 may include a cleaning process before preparation of the dielectric substrate 1, in which the dielectric substrate 1 is sequentially subjected to ultrasonic cleaning sequentially using organic solvents including deionized water, ethanol, isopropyl alcohol and the like for at least 15 min, and then dried by an oven continuously at 75° C. for a certain time depending on the final cleaning solvent.

At S22, as shown in FIG. 9a, forming a first conductive pattern M1 including the first plate 21 on the dielectric substrate 1.

Illustratively, as shown in FIG. 9a, a first bonding layer may be prepared by electroplating, chemical plating and the like, or formed by sputtering, on the dielectric substrate 1. Generally, the first bonding layer may be selected to be made of titanium (Ti), tantalum (Ta), titanium nitride (TiN), tantalum nitride (TaN), or any other metal or metal nitride with high adhesion with glass, and a thickness of the bonding layer may be adjusted as required, and is generally between 30 nm and 100 nm. A first conductive pattern material is deposited on the first bonding layer through a PVD process; and the first conductive pattern material may be selected to be a metal material with good conductivity, such as Au, Al, Ag, Cu, or the like. A thickness of the first conductive pattern material may be set as required, and is generally between 0.2 μm and 2 μm. A layer of photoresist (PR) is coated on a surface of the first conductive pattern material facing away from the dielectric substrate 1. The PR may be selected to be an ordinary photosensitive PR, either positive or negative, a thickness of which should enable complete coverage of a surface of the first conductive pattern material by a certain thickness, and may be set between 1 μm and 4 μm. Then, a mask is used for PR exposure and development to reserve the PR above the pattern of the first plate 21 while the PR in other regions is completely stripped. Then, the first conductive pattern material beyond the pattern is stripped off. When the first conductive pattern material is selected to be Cu, wet etching may be adopted; and when the first conductive pattern material is selected to be Al, wet or dry etching may be adopted. Different etching modes may be selected for different metals. Thereafter, the PR above the metal pattern is stripped off to form a first conductive pattern M1 including the first plate 21.

At S23, as shown in FIG. 9b, forming a second conductive pattern M1 on a side of the first conductive pattern M2 facing away from the dielectric substrate 1.

The second conductive pattern M2 includes a second plate 22 of the capacitor 2, and the second plate 22 is electrically connected to the inductor 3.

Illustratively, as shown in FIG. 9b, an insulation layer material may be deposited on a side of the first conductive pattern M1 facing away from the dielectric substrate 1 through a CVD process, and the insulation layer material may be selected to be silicon nitride (SiNx), and used as a dielectric layer between upper and lower plates of the capacitor 2. A thickness of the insulation layer material may be designed and determined according to requirements of a value of the capacitor 2, and may be generally set between 80 nm and 200 nm. Then, a second conductive pattern material may be deposited on a side of the insulation layer material facing away from the dielectric substrate 1 through a PVD process. The second conductive pattern material may be selected to be a material with good conductivity, such as Cu and Al, and have a thickness set as required, which may be selected between 0.2 μm and 2 μm. A second bonding layer may be formed between the insulation layer material and the second conductive pattern material. The second bonding layer may be selected to be made of Ti, Ta, TiN, TaN, or any other metal or metal nitride with high adhesion, and have a thickness adjustable according to the process capability, which may be selected between 30 nm and 100 nm. Then, a layer of PR is coated on a side of the second conductive pattern material facing away from the dielectric substrate 1. The PR may be selected to be an ordinary photosensitive PR, either positive or negative, a thickness of which should enable complete coverage of a surface of the second conductive pattern material by a certain thickness, and may be set between 1 μm and 4 μm. Then, a mask is used for PR exposure and development to reserve the PR above the pattern of the second plate 22 while the PR in other regions is completely stripped. Then, the second conductive pattern material beyond the pattern is stripped off. When the second conductive pattern material is selected to be Cu, wet etching may be adopted; and when the second conductive pattern material is selected to be Al, wet or dry etching may be adopted. Different etching modes may be selected for different metals. Thereafter, the PR above the metal pattern is stripped off to form a second conductive pattern M2 including the second plate 22. Then, a layer of PR is formed on a side of the second conductive pattern M2 facing away from the dielectric substrate 1. The PR may be selected to be an ordinary photosensitive PR, either positive or negative, a thickness of which should enable complete coverage of a surface of the insulation layer material by a certain thickness, and may be set between 1 μm and 4 μm. Then, a mask is used for PR exposure and development to reserve the PR above the pattern of the insulation layer 40 while the PR in other regions is completely stripped. Then, the insulation layer material beyond the pattern is stripped off, typically by dry etching. Then, the PR above the insulation layer 40 pattern is stripped off to form the insulation layer 40.

At S24, as shown in FIG. 9c, forming a second interlayer insulation layer 42 on a side of the second conductive pattern M2 facing away from the dielectric substrate 1.

The second interlayer insulation layer 42 is formed with a second connection via via2 running through the second interlayer insulation layer 42 in a thickness direction of the second interlayer insulation layer 42, through which the second plate 22 is electrically connected to the first coil structure 31.

Illustratively, as shown in FIG. 9c, the second interlayer insulation layer 42 may be selected to be made of a photosensitive PI material, a thickness of which is determined according to the design requirement, and is typically between 3 μm and 8 μm. Through exposure and development, the PI material at a lap joint position of the first coil structure 31 and the second plate 22 is stripped off, and then the remaining PI material is cured to form the second connection via via2. The PI material is changed from a soft film to a hard film to increase strength of the film layer. Since the PI material is generally negative, the PI via has a smaller size at a bottom than at a top, and a taper angle may be adjusted between 20° and 90° by changing the process conditions, so as to form the second interlayer insulation layer 42.

At S25, forming multiple layers of third conductive patterns M3 on a side of the second interlayer insulation layer 42 facing away from the dielectric substrate 1, and forming at least one first interlayer insulation layer 41 between adjacent third conductive patterns M3.

The method includes at least: forming, through electroplating, the third conductive pattern M3 including the coil structure on a side of the first interlayer insulation layer 41 facing away from the dielectric substrate 1.

Taking an inductor 3 including three turns of coil structure as an example, the method specifically includes the following steps S251 to S255:

At S251, as shown in FIG. 9d, forming a first coil structure 31 on a side of the second interlayer insulation layer 42 facing away from the dielectric substrate 1.

Step S251 may include preparing by electroplating, chemical plating and the like, or forming by sputtering, a first conductive film as a first seed layer on a side of the second interlayer insulation layer 42 facing away from the dielectric substrate 1, and then spin-coating, exposing and developing a photoresist, and electroplating and chemically plating a metal on a side of the first seed layer facing away from the dielectric substrate 1 to form the first coil structure 31.

The first conductive film is generally made of Ti, Ta, TiN, TaN, or any other metal or metal nitride with high adhesion. The first coil structure is generally made of a metal material such as Au, Al, Ag, Cu, or the like. The first coil structure 31 generally has a thickness between 3 μm and 7 μm. To ensure flatness of the first coil structure 31, an upper surface (i.e., a surface facing away from the dielectric substrate 1) of the first coil structure 31 may be processed by chemical mechanical polishing (CMP).

Illustratively, the first conductive film may be formed by electroplating through an additive process or a subtractive process. For example, taking the additive process as an example, a first conductive film material is deposited on a side of the second interlayer insulation layer 42 facing away from the dielectric substrate 1 through a PVD process, the first conductive film material is typically selected to be Ti, and has a thickness which may be adjusted as required, so as to ensure that a surface of the second interlayer insulation layer 42 is completely covered, especially that the first conductive film material completely covers an interior of the PI via and a sidewall of the via without breaking. Then, a layer of PR is coated on a side of the first conductive film material facing away from the dielectric substrate 1. The PR may be selected to be an ordinary photosensitive PR, either positive or negative, a thickness of which may be determined according to the thickness of the electroplated first coil structure 31, and is generally greater than the thickness of the electroplated first coil structure 31. Then, a mask is used for PR exposure and development to form a pattern of the first coil structure 31, beyond which the PR is then stripped off. If a positive photoresist is selected, the taper angle of the pattern is generally an acute angle, and considering a taper angle at edges of the subsequent electroplated metal pattern and the subsequent process, it is preferable that the taper angle of the PR pattern is close to a right angle as much as possible. If a negative photoresist is selected, the taper angle of the pattern is generally an obtuse angle. Then, Cu is electroplated on the first seed layer to form a first coil structure material, a thickness of which is determined as required, and may be typically selected between 3 um and 7 um. Then, the remaining PR is stripped off to expose all the remaining first seed layer, and the first seed layer beyond the pattern of the first coil structure 31 is completely etched away, so as to prevent the first seed layer under the first coil structure 31 from being etched to form a chamfer which may affect a bonding force between the film layers. The final form is as shown in FIG. 9d.

Illustratively, as shown in FIG. 9d, among the multiple layers of coil structures, a coil structure closest to the dielectric substrate 1 is a first coil structure 31; and the first coil structure 31 is electrically connected to the second plate 22 through a second connection via via2 running through the second interlayer insulation layer 42 between the first coil structure 31 and the second plate 22.

At S252, as shown in FIG. 9e, forming a first first interlayer insulation layer 41 on a side of the first coil structure 31 facing away from the dielectric substrate 1.

Here, the process of forming the first interlayer insulation layer 41 is the same as the specific process of forming the second interlayer insulation layer 42 described above, and repeated descriptions are omitted.

The first first interlayer insulation layer 41 is formed with a first connection via via1 running through the first first interlayer insulation layer 41 in a thickness direction of the first first interlayer insulation layer 41, through which the first coil structure 31 is electrically connected to an adjacent second coil structure 32.

Illustratively, the first first interlayer insulation layer 41 may be selected to be made of a photosensitive PI material. A thickness of the first first interlayer insulation layer 41 may be determined according to design requirements, and is typically between 3 μm and 8 μm.

At S253, as shown in FIG. 9f, forming a second coil structure 32 on a side of the first first interlayer insulation layer 41 facing away from the dielectric substrate 1.

Step S253 may include preparing by electroplating, chemical plating and the like, or forming by sputtering, a second conductive film as a second seed layer on a side of the first first interlayer insulation layer 41 facing away from the dielectric substrate 1, and then spin-coating, exposing and developing a photoresist, and electroplating and chemically plating a metal on a side of the second seed layer facing away from the dielectric substrate 1 to form the second coil structure 32.

The second conductive film is generally made of Ti, Ta, TiN, TaN, or any other metal or metal nitride with high adhesion. The second coil structure is generally made of a metal material such as Au, Al, Ag, Cu, or the like. The second coil structure 32 generally has a thickness between 3 μm and 7 μm. To ensure flatness of the second coil structure 32, an upper surface (i.e., a surface facing away from the dielectric substrate 1) of the second coil structure 32 may be processed by chemical mechanical polishing (CMP).

The specific process of forming the second coil structure 32 may refer to the specific process of forming the first coil structure 31 described above, and repeated descriptions are omitted.

At S254, as shown in FIG. 9g, forming a second first interlayer insulation layer 41 on a side of the second coil structure 32 facing away from the dielectric substrate 1.

Here, the process of forming the first interlayer insulation layer 41 is the same as the specific process of forming the second interlayer insulation layer 42 described above, and repeated descriptions are omitted.

The second first interlayer insulation layer 41 is formed with a first connection via via1 running through the second first interlayer insulation layer 41 in a thickness direction of the second first interlayer insulation layer 41, through which the first coil structure 31 is electrically connected to an adjacent third coil structure 33.

Illustratively, the second first interlayer insulation layer 42 may be selected to be made of a photosensitive PI material. A thickness of the second first interlayer insulation layer 41 may be determined according to design requirements, and is typically between 3 μm and 8 μm.

At S255, as shown in FIG. 9h, forming a third coil structure 33 on a side of the second first interlayer insulation layer 41 facing away from the dielectric substrate 1.

Step S255 may include preparing by electroplating, chemical plating and the like, or forming by sputtering, a third conductive film as a third seed layer on a side of the second first interlayer insulation layer 41 facing away from the dielectric substrate 1, and then spin-coating, exposing and developing a photoresist, and electroplating and chemically plating a metal on a side of the third seed layer facing away from the dielectric substrate 1 to form a third coil structure 33.

The third conductive film is generally made of Ti, Ta, TiN, TaN, or any other metal or metal nitride with high adhesion. The first coil structure is generally made of a metal material such as Au, Al, Ag, Cu, or the like. The second coil structure 32 generally has a thickness between 3 μm and 7 μm. To ensure flatness of the second coil structure 32, an upper surface (i.e., a surface facing away from the dielectric substrate 1) of the second coil structure 32 may be processed by chemical mechanical polishing (CMP).

The specific process of forming the third coil structure 33 may refer to the specific process of forming the first coil structure 31 described above, and repeated descriptions are omitted.

At S26, as shown in FIG. 9i, forming a sixth interlayer insulation layer 46 on a side of the third coil structure 33 facing away from the dielectric substrate 1.

Here, the process of forming the sixth interlayer insulation layer 46 is the same as the specific process of forming the second interlayer insulation layer 42 described above, and repeated descriptions are omitted.

The sixth interlayer insulation layer 46 is formed with a third connection via via3 running through the sixth interlayer insulation layer 46 in a thickness direction of the sixth interlayer insulation layer 46, through which the third coil structure 33 is electrically connected to a connection structure 5.

Illustratively, the sixth interlayer insulation layer 46 may be selected to be made of a photosensitive PI material. A thickness of the six interlayer insulation layer 46 may be determined according to design requirements, and is typically between 3 μm and 8 μm.

At S27, as shown in FIG. 9j, forming a connection structure 5 on a side of the sixth interlayer insulation layer 46 facing away from the dielectric substrate 1.

The connecting structure 5 may be selected to be prepared by a packaging mode corresponding to a solder ball or a copper pillar. The solder ball may be manufactured by printing, ball placement and the like, while the copper pillar may be manufactured by electroplating.

Illustratively, for example, taking the additive process as an example, a fourth conductive film material may be deposited on a side of the sixth interlayer insulation layer 46 facing away from the dielectric substrate 1 through a PVD process, and a fourth conductive film is formed as a fourth seed layer of the connection structure 5. The fourth conductive film material is typically selected to be Ti, and has a thickness which may be adjusted as required and typically selected between 100 nm and 500 nm, so as to ensure that a surface of the sixth interlayer insulation layer 46 is completely covered, especially that the fourth conductive film material completely covers an interior of the PI via and a sidewall of the via without breaking. Then, a layer of PR is coated on a side of the fourth conductive film material facing away from the dielectric substrate 1. The PR may be selected to be an ordinary photosensitive PR, either positive or negative, a thickness of which may be determined according to a thickness of the electroplated connection structure 5, and is generally greater than the thickness of the electroplated connection structure 5. Then, a mask is used for PR exposure and development to form a pattern of the connection structure 5, beyond which the PR is then stripped off. If a positive photoresist is selected, the taper angle of the pattern is generally an acute angle, and considering a taper angle at edges of the subsequent electroplated metal pattern and the subsequent process, it is preferable that the taper angle of the PR pattern is close to a right angle as much as possible. Then, Cu is electroplated on the fourth seed layer to form a first connection sub-layer 51. The first connection sub-layer 51 may have a thickness selected between 20 μm and 60 μm. A barrier layer 53 is formed on a side of the first connection sub-layer 51 facing away from the dielectric substrate 1. The barrier layer 53 may be selected to be made of Ni, and have a thickness selected between 3 μm and 10 μm. An Sn—Ag alloy or Sn is electroplated on a side of the barrier layer 53 facing away from the dielectric substrate 1 to form a second connection sub-layer 52. The second connection sub-layer 52 may have a thickness selected between 20 μm and 50 μm. Then, the remaining PR is stripped off to expose all the remaining fourth seed layer, and the fourth seed layer beyond the pattern of the connection structure 5 is completely etched away, so as to prevent the fourth seed layer under the connection structure 5 from being etched to form a chamfer which may affect a bonding force between the film layers. Then, reflow is performed on the second connection sub-layer 52, so that a top end of the SnAg or Sn film layer is changed from a plane to an arc, so as to ensure the soldering effect of the subsequent device is ensured. The final form is as shown in FIG. 9j.

In the above steps S21 to S27, by means of the coils arranged to be sequentially connected and having projections mostly overlapped, the overall area of the coils in an overlooking plane of the inductor 3 can be reduced, so that the wiring space for the device is saved, and the miniaturization design of the device is facilitated.

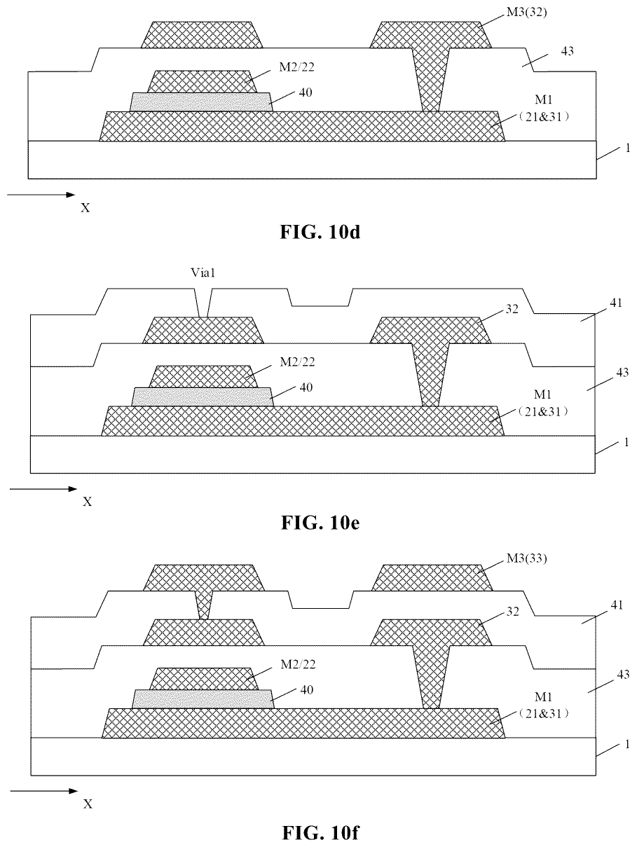

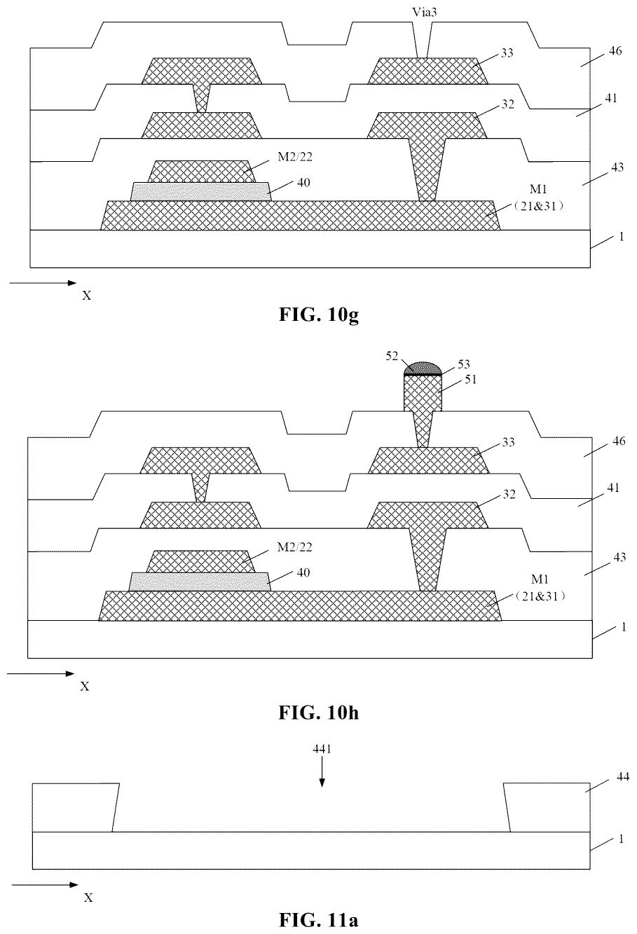

In some embodiments, FIGS. 10a to 10h are schematic diagrams illustrating preparation of the filter shown in FIG. 5 according to an embodiment of the present disclosure. As shown in FIGS. 10a to 10h, the method includes the following steps S31 to S37:

At S31, providing a dielectric substrate 1.

Illustratively, a dielectric substrate 1, with a thickness of 0.15 mm to 2 mm and applicable to mass production, is prepared according to the requirements of process equipment, where the dielectric substrate 1 may be selected to be made of glass, high-resistivity silicon, ceramic, or any other high-insulating and low-dielectric-loss material. Step S31 may include a cleaning process before preparation of the dielectric substrate 1, in which the dielectric substrate 1 is sequentially subjected to ultrasonic cleaning sequentially using organic solvents including deionized water, ethanol, isopropyl alcohol and the like for at least 15 min, and then dried by an oven continuously at 75° C. for a certain time depending on the final cleaning solvent.

At S32, forming a first conductive pattern M1 including the first plate 21 and the first coil structure 31 on the dielectric substrate 1.

As shown in FIG. 10a, step S32 may include preparing by electroplating, chemical plating and the like, or forming by sputtering, a first conductive film as a first seed layer on the dielectric substrate 1; and then spin-coating, exposing and developing a photoresist, and electroplating and chemically plating a metal on a side of the first seed layer facing away from the dielectric substrate 1, to form the first conductive pattern M1 including the first plate 21 and the first coil structure 31.

The first seed layer is generally made of Ti, Ta, TiN, TaN, or any other metal or metal nitride with high adhesion, and a thickness of the first seed layer may be adjusted as required, and is generally between 30 nm and 200 nm; or the first seed layer may be selected to be made of Cu, which has a thickness generally between 0.1 μm and 1 μm. The first conductive pattern M1 is generally made of a metal material such as Au, Al, Ag, Cu, or the like. The first plate 21 and the first coil structure 31 may be integrally formed, and have an overall thickness generally between 3 μm and 7 μm. To ensure flatness of the first plate 21 and the first coil structure 31 integrally formed, an upper surface (i.e., a surface facing away from the dielectric substrate 1) of the first coil structure 31 may be processed by chemical mechanical polishing (CMP).

Illustratively, as shown in FIG. 10a, PR is coated on a side of the first conductive film facing away from the dielectric substrate 1. The PR may be selected to be an ordinary photosensitive PR, either positive or negative, a thickness of which may be selected according to the thickness of the electroplated first conductive pattern M1, and is generally greater than the thickness of the electroplated first conductive pattern M1. Then, a mask is used for PR exposure and development to form a pattern of the first conductive pattern M1, and the PR corresponding to the pattern of the first conductive pattern M1 is stripped off. If a positive photoresist is selected, the taper angle of the pattern is generally an acute angle, and considering a taper angle at edges of the subsequent electroplated metal pattern and the subsequent process, it is preferable that the taper angle of the PR pattern is close to a right angle as much as possible. If a negative photoresist is selected, the taper angle of the pattern is generally an obtuse angle. The product topography shown in FIG. 10a is a negative PR exposed topography. Then, Cu is electroplated on a partial region on the first seed layer not covered by the PR, to form the first plate 21 and the first coil structure 31 integrally formed. Since the electroplated growing metal will completely fill up an interior space of the PR, a taper angle of the M1 metal which is electroplated and grows is determined by a property of the PR. If a positive PR is selected, the taper angle of a sidewall of the M1 metal which is electroplated and grows through an additive process is an obtuse angle, that is, an upper surface of the metal is longer than a lower surface. If a negative PR is selected, the taper angle of the metal which is electroplated and grows through an additive process is an acute angle. The figure shows an M1 layer metal topography formed by electroplating the negative PR through an additive process, where slight undulations can be observed microscopically on a surface of the electroplated metal, and the roughness is generally higher than 10 nm. Then, the remaining PR is stripped off to expose all the first seed layer. Thereafter, the first seed layer beyond coverage of the metal Cu is completely etched away to form the first conductive pattern M1.

At S33, forming a second conductive pattern M1 on a side of the first conductive pattern M2 facing away from the dielectric substrate 1.

The second conductive pattern M2 includes a second plate 22 of the capacitor 2. The first plate 21 is electrically connected to the inductor 3.

Illustratively, as shown in FIG. 10b, an insulation layer material may be deposited on a side of the first conductive pattern M1 facing away from the dielectric substrate 1 through a CVD process, and the insulation layer material may be selected to be silicon nitride (SiNx), and used as an insulation layer 40 between upper and lower plates of the capacitor 2. A thickness of the insulation layer material may be designed and determined according to requirements of a value of the capacitor 2, and may be generally set between 80 nm and 200 nm. Then, a second conductive pattern material may be deposited on a side of the insulation layer material facing away from the dielectric substrate 1 through a PVD process. The second conductive pattern material may be selected to be a material with good conductivity, such as Cu and Al, and have a thickness set as required, which may be selected between 0.2 μm and 2 μm. A bonding layer may be formed between the insulation layer material and the second conductive pattern material. The bonding layer may be selected to be made of Ti, Ta, TiN, TaN, or any other metal or metal nitride with high adhesion, and have a thickness adjustable according to the process capability, which may be selected between 30 nm and 100 nm. Then, a layer of PR is coated on a side of the second conductive pattern material facing away from the dielectric substrate 1. The PR may be selected to be an ordinary photosensitive PR, either positive or negative, a thickness of which should enable complete coverage of a surface of the second conductive pattern material by a certain thickness, and may be set between 1 μm and 4 μm. Then, a mask is used for PR exposure and development to reserve the PR above the pattern of the second plate 22 while the PR in other regions is completely stripped. Then, the second conductive pattern material beyond the pattern is stripped off. When the second conductive pattern material is selected to be Cu, wet etching may be adopted; and when the second conductive pattern material is selected to be Al, wet or dry etching may be adopted. Different etching modes may be selected for different metals. Thereafter, the PR above the metal pattern is stripped off to form a second conductive pattern M2 including the second plate 22. Then, a layer of PR is formed on a side of the second conductive pattern M2 facing away from the dielectric substrate 1. The PR may be selected to be an ordinary photosensitive PR, either positive or negative, a thickness of which should enable complete coverage of a surface of the insulation layer material by a certain thickness, and may be set between 1 μm and 4 μm. Then, a mask is used for PR exposure and development to reserve the PR above the pattern of the insulation layer 40 while the PR in other regions is completely stripped. Then, the insulation layer material beyond the pattern is stripped off, typically by dry etching. Then, the PR above the insulation layer 40 pattern is stripped off to form the insulation layer 40.

At S34, forming a third interlayer insulation layer 43 on a side of the second conductive pattern M2 facing away from the first conductive pattern M1.

The third interlayer insulation layer 43 covers the second plate 22, and the first plate 21 and the first coil structure 31 integrally formed.

The third interlayer insulation layer 43 is formed with a first connection via via1 running through the third interlayer insulation layer 43 in a thickness direction of the third interlayer insulation layer 43, through which the first coil structure 31 is electrically connected to an adjacent second coil structure 32.

Illustratively, as shown in FIG. 10c, the third interlayer insulation layer 43 may be selected to be made of a photosensitive PI material, a thickness of which is determined according to the design requirement, and is typically between 3 μm and 8 μm. Through exposure and development, the PI material at a lap joint position of the first coil structure 31 and the second plate 22 is stripped off, and then the remaining PI material is cured to form the first connection via via1. The PI material is changed from a soft film to a hard film to increase strength of the film layer. Since the PI material is generally negative, the PI via has a smaller size at a bottom than at a top, and a taper angle may be adjusted between 20° and 90° by changing the process conditions, so as to form the third interlayer insulation layer 43.

It should be noted that a gentler taper angle will lead to a more uniform electroplated metal seed layer subsequently covering the side wall of the via, which makes film peeling less possible, but also causes an increased size of a top of the via. Therefore, the taper angle of the via should be adjusted according to a last size of the metal pattern.

In step S34, by forming the third interlayer insulation layer 43 covering the second plate 22, and the first plate 21 and the first coil structure 31 integrally formed through one patterning process, the capacitor 2 and the first coil structure 31 can be insulated from the second coil structure 32 in an upper layer, thereby reducing the number of process steps and the production cost.

S35, forming multiple layers of third conductive patterns M3 on a side of the third interlayer insulation layer 43 facing away from the dielectric substrate 1, and forming at least one first interlayer insulation layer 41 between adjacent third conductive patterns M3.

Taking an inductor 3 including three turns of coil structure as an example, which specifically includes the following steps S351 to S353:

At S351, as shown in FIG. 10d, forming a second coil structure 32 on a side of the third interlayer insulation layer 43 facing away from the dielectric substrate 1.

Step S351 may include preparing by electroplating, chemical plating and the like, or forming by sputtering, a second conductive film as a second seed layer on a side of the third interlayer insulation layer 43 facing away from the dielectric substrate 1, and then spin-coating, exposing and developing a photoresist, and electroplating and chemically plating a metal on a side of the second seed layer facing away from the dielectric substrate 1 to form the second coil structure 32.

The second conductive film is generally made of Ti, Ta, TiN, TaN, or any other metal or metal nitride with high adhesion. The second coil structure is generally made of a metal material such as Au, Al, Ag, Cu, or the like. The second coil structure 32 generally has a thickness between 3 μm and 7 μm. To ensure flatness of the second coil structure 32, an upper surface (i.e., a surface facing away from the dielectric substrate 1) of the second coil structure 32 may be processed by chemical mechanical polishing (CMP).

Illustratively, a second conductive film material may be deposited on a side of the third interlayer insulation layer 43 facing away from the dielectric substrate 1 through a PVD process, the second conductive film material is typically selected to be Ti, and has a thickness which may be adjusted as required, so as to ensure that a surface of the second interlayer insulation layer 42 is completely covered, especially that the first conductive film material completely covers an interior of the PI via and a sidewall of the via without breaking. In general, the thickness of the second conductive film material may be selected to be greater than 0.2 nm. Then, a layer of PR is coated on a side of the second conductive film material facing away from the dielectric substrate 1. The PR may be selected to be an ordinary photosensitive PR, either positive or negative, a thickness of which may be determined according to the thickness of the electroplated second coil structure 32, and is generally greater than the thickness of the electroplated second coil structure 32. Then, a mask is used for PR exposure and development to form a pattern of the second coil structure 32, beyond which the PR is then stripped off. If a positive photoresist is selected, the taper angle of the pattern is generally an acute angle, and considering a taper angle at edges of the subsequent electroplated metal pattern and the subsequent process, it is preferable that the taper angle of the PR pattern is close to a right angle as much as possible. If a negative photoresist is selected, the taper angle of the pattern is generally an obtuse angle. Then, Cu is electroplated on the second seed layer to form a second coil structure material. Then, the remaining PR is stripped off to expose all the remaining second seed layer, and the second seed layer beyond the pattern of the second coil structure 32 is completely etched away, so as to prevent the second seed layer under the second coil structure 32 from being etched to form a chamfer which may affect a bonding force between the film layers. The final form is as shown in FIG. 10d.

At S352, as shown in FIG. 10e, forming a first interlayer insulation layer 41 on a side of the second coil structure 32 facing away from the dielectric substrate 1.

Here, the process of forming the first interlayer insulation layer 41 is the same as the specific process of forming the third interlayer insulation layer 43 described above, and repeated descriptions are omitted.

The first interlayer insulation layer 41 is formed with a first connection via via1 running through the first interlayer insulation layer 41 in a thickness direction of the first interlayer insulation layer 41, through which the second coil structure 32 is electrically connected to an adjacent third coil structure 33.

Illustratively, the first interlayer insulation layer 41 may be selected to be made of a photosensitive PI material. A thickness of the first interlayer insulation layer 41 may be determined according to design requirements, and is typically between 3 μm and 8 μm.

At S353, as shown in FIG. 10f, forming a third coil structure 33 on a side of the first interlayer insulation layer 41 facing away from the dielectric substrate 1.

Step S353 may include preparing by electroplating, chemical plating and the like, or forming by sputtering, a third conductive film as a third seed layer on a side of the first interlayer insulation layer 41 facing away from the dielectric substrate 1, and then spin-coating, exposing and developing a photoresist, and electroplating and chemically plating a metal on a side of the third seed layer facing away from the dielectric substrate 1 to form a third coil structure 33.

The third conductive film is generally made of Ti, Ta, TiN, TaN, or any other metal or metal nitride with high adhesion. The third coil structure 33 is generally made of a metal material such as Au, Al, Ag, Cu, or the like. The third coil structure 33 generally has a thickness between 3 μm and 7 μm. To ensure flatness of the third coil structure 33, an upper surface (i.e., a surface facing away from the dielectric substrate 1) of the second coil structure 32 may be processed by chemical mechanical polishing (CMP).

The specific process of forming the third coil structure 33 may refer to the specific process of forming the second coil structure 32 described above, and repeated descriptions are omitted.

At S36, as shown in FIG. 10g, forming a sixth interlayer insulation layer 46 on a side of the third coil structure 33 facing away from the dielectric substrate 1.

Here, the process of forming the sixth interlayer insulation layer 46 is the same as the specific process of forming the third interlayer insulation layer 43 described above, and repeated descriptions are omitted.

The sixth interlayer insulation layer 46 is formed with a third connection via via3 running through the sixth interlayer insulation layer 46 in a thickness direction of the sixth interlayer insulation layer 46, through which the third coil structure 33 is electrically connected to a connection structure 5.

Illustratively, the sixth interlayer insulation layer 46 may be selected to be made of a photosensitive PI material. A thickness of the sixth interlayer insulation layer 46 may be determined according to design requirements, and is typically between 3 μm and 8 μm.

At S37, as shown in FIG. 10h, forming a connection structure 5 on a side of the sixth interlayer insulation layer 46 facing away from the dielectric substrate 1.

For the specific process of step S37, reference may be made to the specific implementation process of forming the connection structure 5 in step S27, and repeated descriptions are omitted.

Compared with the embodiments of steps S21 to S27, in the embodiment corresponding to steps S31 to S37, the first plate 21 of the capacitor 2 and the first coil structure 31 of the inductor 3 are disposed in the same layer and connected to be integrally formed, thereby reducing the number of process steps and the production cost. In addition, by generating the first plate 21 and the first coil structure 31 integrally formed, an overall structural thickness of the inductor 3 can be effectively reduced, thereby facilitating a lightweight design of the device. Specifically, compared with the preparation process of the filter shown in FIG. 4, the present embodiment can reduce a layer of film metal, a layer of interlayer insulation layer, so that the process flow of the present embodiment is shorter while involving less risks and lower cost.

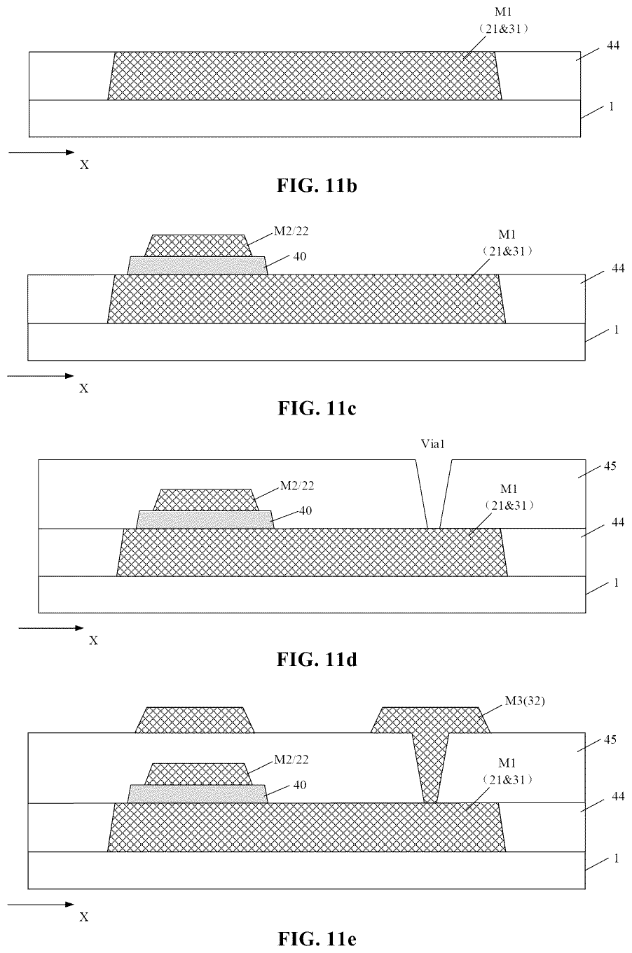

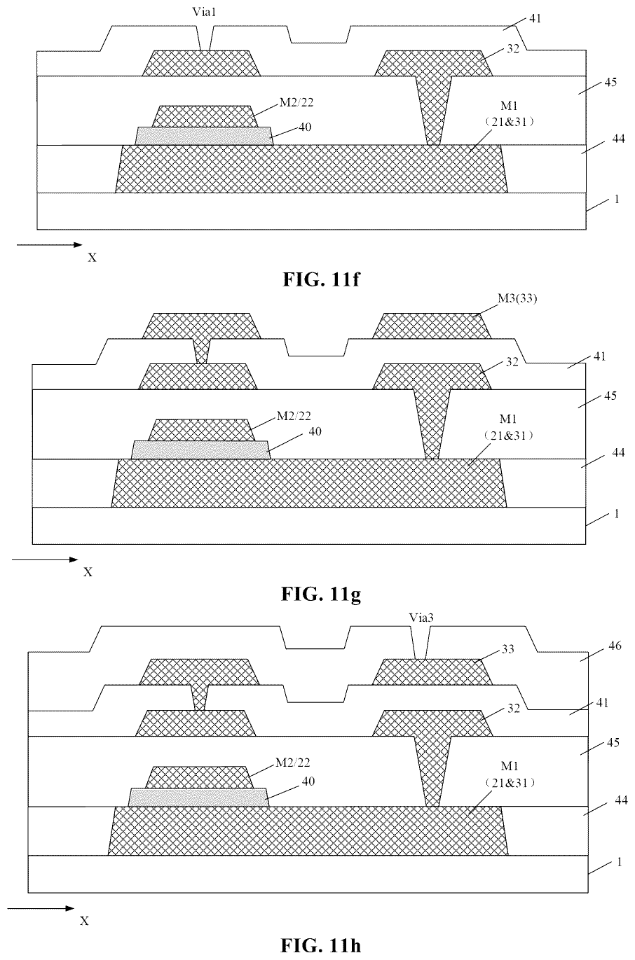

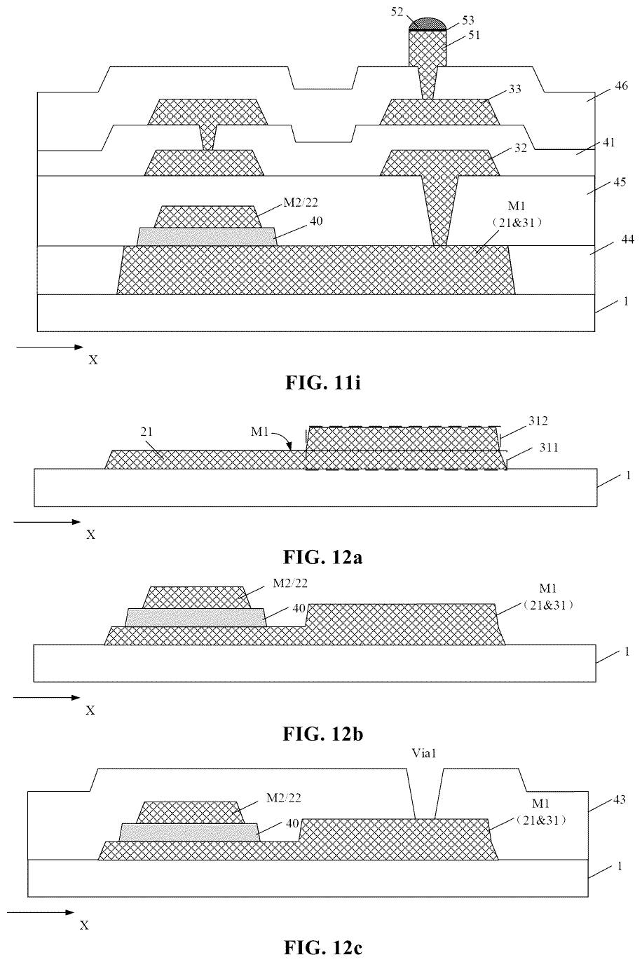

In some embodiments, FIGS. 11a to 11i are schematic diagrams illustrating preparation of the filter shown in FIG. 6 according to an embodiment of the present disclosure. As shown in FIGS. 11a to 11i, the method includes the following steps S41 to S48:

At S41, providing a dielectric substrate 1.

Reference may be made to the detailed description of step S31, and repeated descriptions are omitted.

At S42, as shown in FIG. 11a, forming a fourth interlayer insulation layer 44 on the dielectric substrate 1.

The fourth interlayer insulation layer 44 includes a first receiving portion 441 running through the fourth interlayer insulation layer 44 in a thickness direction of the fourth interlayer insulation layer 44.

Illustratively, the fourth interlayer insulation layer 44 may be selected to be made of a photosensitive PI material, or an oxide film such as SiNx or SiO2. When SiNx or SiO2 is used, a film layer is firstly deposited on a glass surface, and then a PR is exposed and developed, and the oxide film is subjected to dry etching to form a pattern of the fourth interlayer insulation layer 44. The photosensitive PI material has the advantages of low material stress, which can effectively reduce warpage of glass due to stress, and help to obtain a more uniform pattern. With the fourth interlayer insulation layer 44 serving as a stop layer of the CMP process, and sharing a pressure applied to the metal layer during the DMP process at the same time, collapse of the metal under pressure can be avoided, as shown in FIG. 11a, where the process flow is shown with a photosensitive PI material.

Illustratively, the fourth interlayer insulation layer 44 is selected to be made of a photosensitive PI material, a thickness of which is determined according to the requirement on the thickness of the first conductive pattern M1, and is typically between 3 μm and 8 μm. The PI material in a pattern region of the first conductive pattern M1 may be stripped by exposure and development, and then the remaining PI material cured to get the PI layer changed from a soft film to a hard film to increase strength of the film layer. Since the PI material is generally negative, the PI pattern has a smaller size at a bottom than at a top, and it is preferable that the taper angle is close to a right angle as much as possible, so as to avoid a chamfer at the bottom which may affect deposition of a subsequent seed layer.

At S43, as shown in FIG. 11b, filling the first plate 21 and the first coil structure 31 integrally formed in the first receiving portion 441 to form the first conductive pattern M1.

A surface of the first plate 21 and the first coil structure 31 integrally formed facing away from the dielectric substrate 1 is flush with a surface of the fourth interlayer insulation layer 44 facing away from the dielectric substrate 1.

As shown in FIG. 11b, step S42 may include preparing by electroplating, chemical plating and the like, or forming by sputtering, a first conductive film as a first seed layer on the dielectric substrate 1; and then spin-coating, exposing and developing a photoresist, and electroplating and chemically plating a metal on a side of the first seed layer facing away from the dielectric substrate 1 to form the first conductive pattern M1 including the first plate 21 and the first coil structure 31.

The first seed layer is generally made of Ti, Ta, TiN, TaN, or any other metal or metal nitride with high adhesion, and a thickness of the first seed layer may be adjusted as required. The first conductive pattern M1 is generally made of a metal material such as Au, Al, Ag, Cu, or the like. The first plate 21 and the first coil structure 31 may be integrally formed and have an overall thickness generally between 3 μm and 7 μm. To ensure flatness of the first plate 21 and the first coil structure 31 integrally formed, an upper surface (i.e., a surface facing away from the dielectric substrate 1) of the first coil structure 31 may be processed by chemical mechanical polishing (CMP).

Illustratively, a first seed layer is deposited on the fourth interlayer insulation layer 44 through a PVD process, where it is ensured that the first seed layer completely covers the fourth interlayer insulation layer 44, especially that the first seed layer completely covers side walls of the fourth interlayer insulation layer 44 in first receiving portion 441 without breaking. An additive process may be used to electroplate Cu on a surface of the first seed layer facing away from the dielectric substrate 1, typically ensuring that the electroplated Cu metal grows beyond the first receiving portion 441. The electroplated Cu is present at a surface of the fourth interlayer insulation layer 44 facing away from the dielectric substrate 1. Then, the electroplated metal and the first seed layer higher than the PI surface are stripped by a CMP process to form the first plate 21 and the first coil structure 31 integrally formed, and a surface of the first plate 21 and the first coil structure 31 integrally formed facing away from the dielectric substrate 1 is flush with a surface of the fourth interlayer insulation layer 44 facing away from the dielectric substrate 1.

At S44, as shown in FIG. 11c, forming a second conductive pattern M1 on a side of the first conductive pattern M2 facing away from the dielectric substrate 1.

The second conductive pattern M2 includes a second plate 22 of the capacitor 2. The first plate 21 is electrically connected to the inductor 3.

Reference may be made to the detailed description of step S33, and repeated descriptions are omitted.

At S45, as shown in FIG. 11d, forming a fifth interlayer insulation layer 45 on a side of the second conductive pattern M2 facing away from the first conductive pattern M1.

A surface of the fifth interlayer insulation layer 45 facing away from the dielectric substrate 1 is parallel to a reference plane of the dielectric substrate 1 extending in a first direction X.

The step of forming the fifth insulation layer may be referred to the detailed description of step S34, and repeated descriptions are omitted.

The fifth interlayer insulation layer 45 is formed with a first connection via via1 running through the fifth interlayer insulation layer 45 in a thickness direction of the fifth interlayer insulation layer 45, through which the first coil structure 31 is electrically connected to an adjacent second coil structure 32.

At S46, forming multiple layers of third conductive patterns M3 on a side of the fifth interlayer insulation layer 45 facing away from the dielectric substrate 1, and forming at least one first interlayer insulation layer 41 between adjacent third conductive patterns M3.

Taking an inductor 3 including three turns of coil structure as an example, the method specifically includes the following steps S461 to S463:

At S461, as shown in FIG. 11e, forming a second coil structure 32 on a side of the fifth interlayer insulation layer 45 facing away from the dielectric substrate 1.

For step S461, reference may be made to the process of forming the second coil structure 32 in step S351, and repeated descriptions are omitted.

At S462, as shown in FIG. 11f, forming a first interlayer insulation layer 41 on a side of the second coil structure 32 facing away from the dielectric substrate 1.

For step S462, reference may be made to the process of forming the first interlayer insulation layer 41 in step S352, and repeated descriptions are omitted.

At S463, as shown in FIG. 11g, forming a third coil structure 33 on a side of the first interlayer insulation layer 41 facing away from the dielectric substrate 1.

The third coil structure 33 in step S463 is formed based on the same principle as the second coil structure 32 in step S351, for which reference may be made to the specific implementation process of forming the second coil structure 32 in step S351, and repeated descriptions are omitted.

At S47, as shown in FIG. 11h, forming a sixth interlayer insulation layer 46 on a side of the third coil structure 33 facing away from the dielectric substrate 1.

Here, the sixth interlayer insulation layer 46 is formed based on the same principle as the third interlayer insulation layer 43 in step S34, for which reference may be made to the specific implementation process of forming the third interlayer insulation layer 43 in step S34, and repeated descriptions are omitted.

At S48, as shown in FIG. 11i, forming a connection structure 5 on a side of the sixth interlayer insulation layer 46 facing away from the dielectric substrate 1.

Here, the connection structure 5 is formed based on the same principle as the connection structure 5 in step S24, for which reference may be made to the specific implementation process of forming the connection structure 5 in step S24, and repeated descriptions are omitted.

In the above steps S41 to S48, by providing the surface of the fourth interlayer insulation layer 44 facing away from the dielectric substrate 1 flush with the surface of the first plate 21 and the first coil structure 31 integrally formed facing away from the dielectric substrate 1, opposite surfaces of the fifth interlayer insulation layer 45 disposed above the fourth interlayer insulation layer 44, in the thickness direction of the fifth interlayer insulation layer 45, are parallel to a reference plane of the dielectric substrate 1 extending in a first direction X, so that the undulation degree of some film layers can be reduced, and even further, an interlayer insulation layer surface without undulation can be formed, which can help to achieve a more uniform thickness at different positions of some film layers and thus more uniform performance of the device.

In addition, in the embodiment, a surface roughness of the electroplated metal of the first conductive pattern M1 is reduced by a CMP process, so that a more uniform thickness of the first conductive pattern M1 can be obtained, which can help to control the thickness uniformity of the insulation layer 40, and improve the uniformity of the capacitance value. Further, compared with the preparation process of the filter shown in FIG. 7, a PR process is reduced, thereby shortening the process flow and reducing the cost.

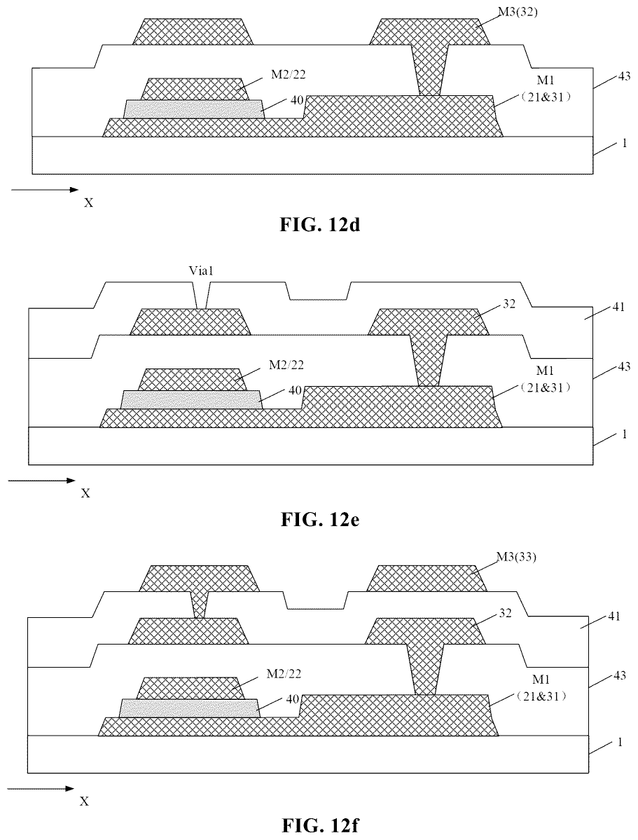

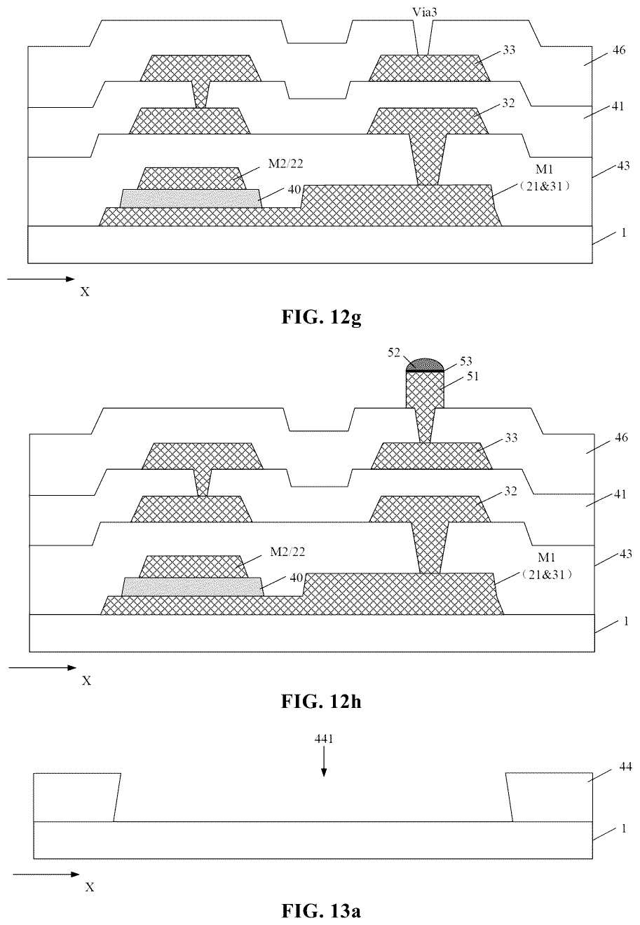

In some embodiments, FIGS. 12a to 12h are schematic diagrams illustrating preparation of the filter shown in FIG. 7 according to an embodiment of the present disclosure. As shown in FIGS. 12a to 12h, the method includes the following steps S51 to S57:

At S51, providing a dielectric substrate 1.

Reference may be made to the detailed description of step S31, and repeated descriptions are omitted.

At S52, as shown in FIG. 12a, forming a first conductive pattern M1 including the first plate 21 and the first coil structure 31 on the dielectric substrate 1.

The first coil structure 31 includes a first sub-coil 311 and a second sub-coil 312 arranged in a stack, and the first sub-coil 311 is located on a side of the second sub-coil 312 close to the dielectric substrate 1.

Step S52 may include preparing by electroplating, chemical plating and the like, or forming by sputtering, a first conductive film as a first seed layer on the dielectric substrate 1, where at least part of a structure of the first seed layer is used as a first sub-coil 311; and then spin-coating, exposing and developing a photoresist, and electroplating and chemically plating a metal on a side of the first seed layer facing away from the dielectric substrate 1 to form a second sub-coil 312 opposite to the first sub-coil 311.

The first conductive film is generally made of Ti, Ta, TiN, TaN, or any other metal or metal nitride with high adhesion. The second sub-coil 312 is generally made of a metal material such as Au, Al, Ag, Cu, or the like. The second sub-coil 312 generally has a thickness between 3 μm and 7 μm. To ensure flatness of the first coil structure 31, an upper surface (i.e., a surface facing away from the dielectric substrate 1) of the first coil structure 31 may be processed by chemical mechanical polishing (CMP).

Illustratively, as shown in FIG. 12a, the first conductive film may be formed by electroplating through an additive process or a subtractive process. For example, taking the additive process as an example, a first conductive film material is deposited on the dielectric substrate 1 through a PVD process, and the first conductive film material is typically selected to be Ti. Then, a layer of PR is coated on a side of the first conductive film material facing away from the dielectric substrate 1. The PR may be selected to be an ordinary photosensitive PR, either positive or negative, a thickness of which may be determined according to the thickness of the electroplated first coil structure 31, and is generally greater than the thickness of the electroplated second sub-coil 312. Then, a mask is used for PR exposure and development to form a pattern of the second sub-coil 312, beyond which the PR is then stripped off. If a positive photoresist is selected, the taper angle of the pattern is generally an acute angle, and considering a taper angle at edges of the subsequent electroplated metal pattern and the subsequent process, it is preferable that the taper angle of the PR pattern is close to a right angle as much as possible. If a negative photoresist is selected, the taper angle of the pattern is generally an obtuse angle. Then, Cu is electroplated on the first seed layer to form a material of the second sub-coil 312, a thickness of which is determined as required, and may be typically selected between 3 um and 7 um. Then, the remaining PR is stripped off to expose all the remaining first seed layer. Then, the PR is coated again on surfaces of the exposed first seed layer and second sub-coil 312 facing away from the dielectric substrate 1. A thickness of the PR is sufficient as long as it is ensured to cover the surface of the second sub-coil 312, and is generally selected between 5 um and 10 um. Then, a mask is used for PR exposure and development to reserve the PR above the pattern of the first plate 21 while the PR in other regions is completely stripped. Then, the first seed layer corresponding to a portion beyond the PR covered pattern is stripped off to form the first plate 21, the first sub-coil 311, and the second sub-coil 312 which are integrally formed.

At S53, as shown in FIG. 12b, forming a second conductive pattern M1 on a side of the first conductive pattern M2 facing away from the dielectric substrate 1.

The second conductive pattern M2 includes a second plate 22 of the capacitor 2. The first plate 21 and the first sub-coil 311 are integrally formed.

Here, the second conductive pattern M2 is formed based on the same principle as the second conductive pattern M2 in step S33, for which reference may be made to the specific implementation process of forming the second conductive pattern M2 in step S33, and repeated descriptions are omitted.

At S54, as shown in FIG. 12c, forming a third interlayer insulation layer 43 on a side of the second conductive pattern M2 facing away from the first conductive pattern M1.

Here, the third interlayer insulation layer 43 is formed based on the same principle as the third interlayer insulation layer 43 in step S34, for which reference may be made to the specific implementation process of forming the third interlayer insulation layer 43 in step S34, and repeated descriptions are omitted.

At S55, forming multiple layers of third conductive patterns M3 on a side of the third interlayer insulation layer 43 facing away from the dielectric substrate 1, and forming at least one first interlayer insulation layer 41 between adjacent third conductive patterns M3.

Taking an inductor 3 including three turns of coil structure as an example, the method specifically includes the following steps S551 to S553:

At S551, as shown in FIG. 12d, forming a second coil structure 32 on a side of the third interlayer insulation layer 43 facing away from the dielectric substrate 1.

At S552, as shown in FIG. 12e, forming a first interlayer insulation layer 41 on a side of the second coil structure 32 facing away from the dielectric substrate 1.

At S553, as shown in FIG. 12f, forming a third coil structure 33 on a side of the first interlayer insulation layer 41 facing away from the dielectric substrate 1.

At S56, as shown in FIG. 12g, forming a sixth interlayer insulation layer 46 on a side of the third coil structure 33 facing away from the dielectric substrate 1.

At S57, as shown in FIG. 12h, forming a connection structure 5 on a side of the sixth interlayer insulation layer 46 facing away from the dielectric substrate 1.

The third conductive pattern M3, the sixth interlayer insulation layer 46 and the connection structure 5 may be formed in steps S55 to S57 based on the same principle as the third conductive pattern M3, the sixth interlayer insulation layer 46 and the connection structure 5 in steps S35 to S37, respectively, for which reference may be made to the specific implementation process in steps S35 to S37, and repeated descriptions are omitted.

In the filter prepared and formed according to steps S51 to S57, the shared first electrode and first sub-coil are manufactured and formed through a PVD process, so that the metal has a higher surface roughness than the electroplated metal, which can help to control the thickness uniformity of the insulation layer 40, and improve the uniformity of the capacitance value. Further, since the shared first electrode and first sub-coil are seed layers of the second sub-coil, an additional PVD process of a thin metal layer is omitted for the first coil structure. In addition, the first electrode may be directly connected to the first sub-coil and the second sub-coil via metal without any via as a lap joint between the insulation layers, thereby reducing process risks.

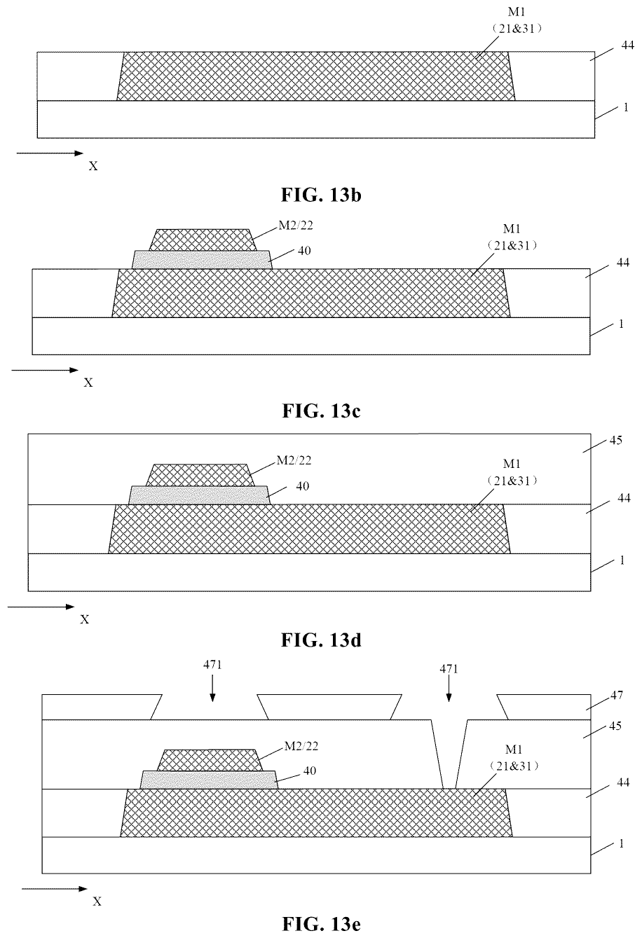

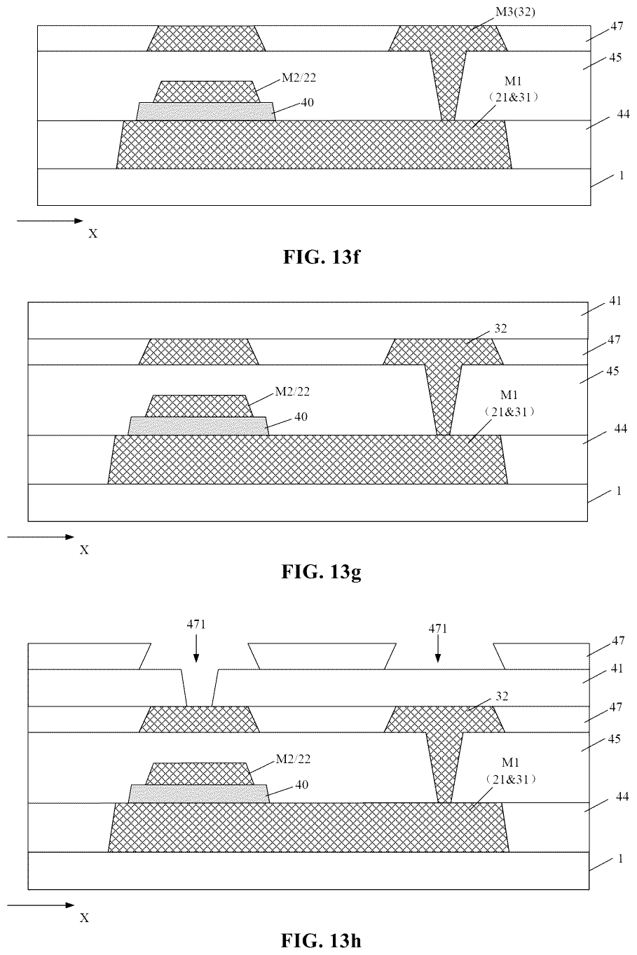

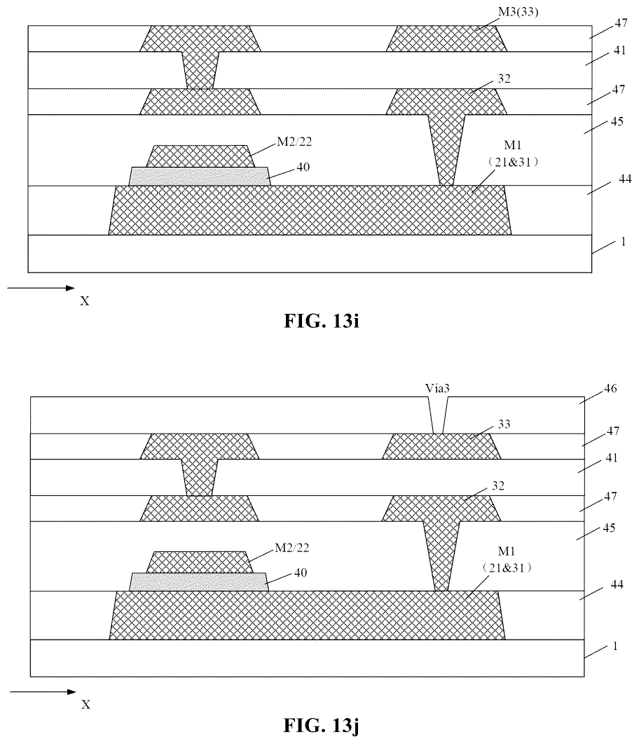

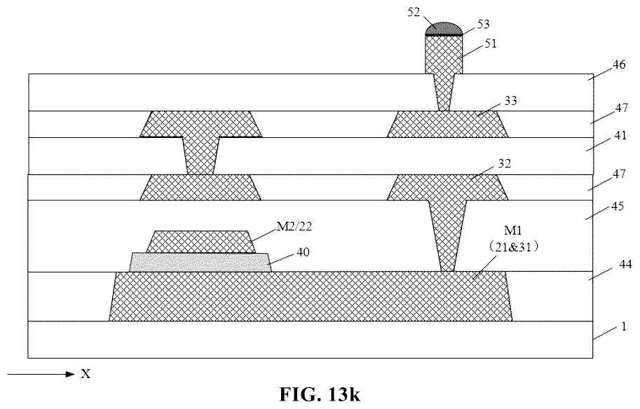

In some embodiments, FIGS. 13a to 13k are schematic diagrams illustrating preparation of the filter shown in FIG. 8 according to an embodiment of the present disclosure. As shown in FIGS. 13a to 13k, the method includes the following steps S61 to S68:

At S61, providing a dielectric substrate 1.

Reference may be made to the detailed description of step S41, and repeated descriptions are omitted.

At S62, as shown in FIG. 13a, forming a fourth interlayer insulation layer 44 on the dielectric substrate 1.

Reference may be made to the detailed description of step S42, and repeated descriptions are omitted.

At S63, as shown in FIG. 13b, filling the first plate 21 and the first coil structure 31 integrally formed in the first receiving portion 441 to form the first conductive pattern M1.

Reference may be made to the detailed description of step S43, and repeated descriptions are omitted.

At S64, as shown in FIG. 13c, forming a second conductive pattern M1 on a side of the first conductive pattern M2 facing away from the dielectric substrate 1.

Reference may be made to the detailed description of step S44, and repeated descriptions are omitted.

At S65, as shown in FIG. 13d, forming a fifth interlayer insulation layer 45 on a side of the second conductive pattern M2 facing away from the first conductive pattern M1.

Reference may be made to the detailed description of step S45, and repeated descriptions are omitted.

At S66, forming multiple layers of third conductive patterns M3 on a side of the fifth interlayer insulation layer 45 facing away from the dielectric substrate 1, and forming at least one first interlayer insulation layer 41 between adjacent third conductive patterns M3.

Taking an inductor 3 including three turns of coil structure as an example, the method specifically includes the following steps S661 to S665:

At S661, as shown in FIG. 13e, forming a first seventh interlayer insulation layer 47 on a side of the fifth interlayer insulation layer 45 facing away from the dielectric substrate 1.

The first seventh interlayer insulation layer 47 includes a second receiving portion 471 running through the first seventh interlayer insulation layer 47 in a thickness direction of the first seventh interlayer insulation layer 47.

Here, the seventh interlayer insulation layer 47 is formed based on the same principle as the fourth interlayer insulation layer 44 in step S42, for which reference may be made to the specific implementation process of forming the fourth interlayer insulation layer 44 in step S42, and repeated descriptions are omitted.

At S662, as shown in FIG. 13f, filling a coil structure material of the inductor 3 in the second receiving portion 471 of the first seventh interlayer insulation layer 47 to form the second coil structure 32.

A surface of the second coil structure 32 facing away from the dielectric substrate 1 is flush with a surface of the seventh interlayer insulation layer 47 facing away from the dielectric substrate 1.

Here, the second coil structure 32 is formed based on the same principle as the first plate 21 and the first coil structure 31 integrally formed in step S43, for which reference may be made to the specific implementation process of forming the first conductive pattern M1 in step S43, and repeated descriptions are omitted.

At S663, as shown in FIG. 13g, forming a first interlayer insulation layer 41 on a side of the second coil structure 32 facing away from the dielectric substrate 1.

Here, the first interlayer insulation layer 41 is formed based on the same principle as the fifth interlayer insulation layer 45 in S45, for which reference may be made to the specific implementation process of forming the fifth interlayer insulation layer 45 in step S45, and repeated descriptions are omitted.

Here, the first interlayer insulation layer includes a first surface and a second surface disposed opposite to each other in a thickness direction of the first interlayer layer, and the first surface and the second surface are both parallel to a reference plane of the dielectric substrate 1 extending in a first direction X.

At S664, as shown in FIG. 13h, forming a second seventh interlayer insulation layer 47 on a side of the first interlayer insulation layer 41 facing away from the dielectric substrate 1.

The second seventh interlayer insulation layer 47 includes a second receiving portion 471 running through the second seventh interlayer insulation layer 47 in a thickness direction of the second seventh interlayer insulation layer 47.

Here, the seventh interlayer insulation layer 47 is formed based on the same principle as the fourth interlayer insulation layer 44 in step S42, for which reference may be made to the specific implementation process of forming the fourth interlayer insulation layer 44 in step S42, and repeated descriptions are omitted.

At S665, as shown in FIG. 13i, filling a coil structure material of the inductor 3 in the second receiving portion 471 of the second seventh interlayer insulation layer 47 to form a third coil structure 33.

A surface of the third coil structure 33 facing away from the dielectric substrate 1 is flush with a surface of the second interlayer insulation layer 42 facing away from the dielectric substrate 1.

The third coil structure 33 in step S665 is formed based on the same principle as the first conductive pattern M1 in step S43, for which reference may be made to the specific implementation process of forming the first conductive pattern M1 in step S43, and repeated descriptions are omitted.

At S67, as shown in FIG. 13j, forming a sixth interlayer insulation layer 46 on a side of the third coil structure 33 facing away from the dielectric substrate 1.

Here, the sixth interlayer insulation layer 46 is formed based on the same principle as the fifth interlayer insulation layer 45 in S45, for which reference may be made to the specific implementation process of forming the fifth interlayer insulation layer 45 in step S45, and repeated descriptions are omitted.

Here, the sixth interlayer insulation layer includes a first surface and a second surface disposed opposite to each other in a thickness direction of the sixth interlayer insulation layer, and the first surface and the second surface are both parallel to a reference plane of the dielectric substrate 1 extending in a first direction X.

At S68, as shown in FIG. 13k, forming a connection structure 5 on a side of the sixth interlayer insulation layer 46 facing away from the dielectric substrate 1.

Here, the connection structure 5 is formed based on the same principle as the connection structure 5 in step S24, for which reference may be made to the specific implementation process of forming the connection structure 5 in step S24, and repeated descriptions are omitted.

Through the process of steps S61 to S68, an interlayer insulation layer surface without undulation is formed, which can help to achieve a more uniform thickness at different positions of each film layer and thus more uniform performance of the device.

In addition, an embodiment the present disclosure further provides an electronic apparatus, which may include any one of the filters described above. Other essential components of the electronic apparatus are regarded as present by those skilled in the art, which are not described herein and should not be construed as limiting the present disclosure.

It will be appreciated that the above implementations are merely exemplary implementations for the purpose of illustrating the principle of the present disclosure, and the present disclosure is not limited thereto. Various modifications and improvements can be made by those skilled in the art without departing from the spirit and essence of the disclosure. Accordingly, all of the modifications and improvements also fall into the protection scope of the present disclosure.

1. A filter, comprising a dielectric substrate having at least one capacitor and at least one inductor disposed thereon, wherein
the capacitor comprises a first plate and a second plate opposite to each other, and the first plate is located on a side of the second plate close to the dielectric substrate; and at least one of the first plate or the second plate is electrically connected to the inductor;
the inductor comprises multiple layers of coil structures which are sequentially arranged on the dielectric substrate, and at least one first interlayer insulation layer is between adjacent coil structures; and the coil structures of adjacent layers are electrically connected together through a first connection via running through the first interlayer insulation layer between the coil structures; and
orthographic projections of any two of the multiple layers of coil structures on the dielectric substrate partially overlap each other.

2. The filter according to claim 1, wherein the capacitor is on a side of the inductor close to the dielectric substrate, and at least one second interlayer insulation layer is between the capacitor and the inductor.

3. The filter according to claim 2, wherein among the multiple layers of coil structures, a coil structure closest to the dielectric substrate is a first coil structure; and the second plate is electrically connected to the first coil structure
wherein the capacitor further comprises a first lead terminal, wherein
the first lead terminal and the second plate are in the same layer and integrally formed; and the first lead terminal is electrically connected to the first coil structure through a second connection via running through the second interlayer insulation layer between the second plate and the first coil structure.

4. (canceled)

5. The filter according to claim 1, wherein among the multiple layers of coil structures, a coil structure closest to the dielectric substrate is a first coil structure; and
the first plate and the first coil structure are in the same layer and electrically connected together.

6. The filter according to claim 5, wherein the first plate and the first coil structure are integrally formed.

7. The filter according to claim 6, wherein among the multiple layers of coil structures, a coil structure adjacent to the first coil structure is a second coil structure; and
a third interlayer insulation layer is between the second coil structure and the dielectric substrate, and covers the second plate, and the first plate and the first coil structure integrally formed.

8. The filter according to claim 6, wherein among the multiple layers of coil structures, a coil structure adjacent to the first coil structure is a second coil structure;
a fourth interlayer insulation layer and a fifth interlayer insulation layer are between the second coil structure and the dielectric substrate, wherein the fourth interlayer insulation layer is provided with a first receiving portion running through the fourth interlayer insulation layer in a thickness direction of the fourth interlayer insulation layer, into which the first plate and the first coil structure integrally formed are defined, and a surface of the first plate and the first coil structure integrally formed facing away from the dielectric substrate is flush with a surface of the fourth interlayer insulation layer facing away from the dielectric substrate; and
the fifth interlayer insulation layer is on a side of the fourth interlayer insulation layer facing away from the dielectric substrate, and covers the second plate.

9. The filter according to claim 1, wherein among the multiple layers of coil structures, a coil structure closest to the dielectric substrate is a first coil structure;
the first coil structure comprises a first sub-coil and a second sub-coil arranged in a stack, and the first sub-coil is located on a side of the second sub-coil close to the dielectric substrate; and
the first plate and the first sub-coil are in the same layer and electrically connected together
wherein the first plate and the first sub-coil are integrally formed.

10. (canceled)

11. The filter according to claim 1, further comprising a connection structure, wherein the connection structure is on a side of the inductor facing away from the dielectric substrate, and electrically connected to a third coil structure in the inductor furthest from the dielectric substrate through a third connection via running through a sixth interlayer insulation layer between the connection structure and the third coil structure.

12. The filter according to claim 1, wherein the first interlayer insulation layer between any adjacent coil structures comprises a first surface and a second surface opposite to each other in a thickness direction of the first interlayer insulation layer, and the first surface and the second surface are both parallel to a reference plane of the dielectric substrate extending in a first direction.

13. The filter according to claim 1, wherein a seventh interlayer insulation layer in the same layer as any of the coil structures comprises a first surface and a second surface opposite to each other in a thickness direction of the seventh interlayer insulation layer, and the first surface and the second surface are both parallel to a reference plane of the dielectric substrate extending in a first direction.

14. A method for preparing a filter, comprising: providing a dielectric substrate, on which at least one capacitor and at least one inductor are formed; wherein forming the at least one capacitor and the at least one inductor comprises:
forming a first conductive pattern on the dielectric substrate, wherein the first conductive pattern comprises at least a first plate of the capacitor;
forming a second conductive pattern on a side of the first conductive pattern facing away from the dielectric substrate, wherein the second conductive pattern comprises a second plate of the capacitor; and at least one of the second plate or the first plate is electrically connected to the inductor; and
forming multiple layers of third conductive patterns on a side of the second conductive pattern facing away from the dielectric substrate, and forming at least one first interlayer insulation layer between adjacent third conductive patterns, wherein the third conductive patterns comprise coil structures of the inductor, and the coil structures of adjacent layers are electrically connected together through a first connection via running through the first interlayer insulation layer between the coil structures; and orthographic projections of any two of the multiple layers of coil structures on the dielectric substrate partially overlap each other.

15. The method for preparing a filter according to claim 14, wherein forming the first conductive pattern on the dielectric substrate comprises: forming a first conductive pattern comprising the first plate on the dielectric substrate; and
forming the multiple layers of third conductive patterns on the side of the second conductive pattern facing away from the dielectric substrate comprises: forming multiple layers of coil structures on the side of the second conductive pattern facing away from the dielectric substrate, wherein among the multiple layers of coil structures, a coil structure closest to the dielectric substrate is a first coil structure; and the first coil structure is electrically connected to the second plate through a second connection via running through a second interlayer insulation layer between the first coil structure and the second plate.

16. The method for preparing a filter according to claim 14, wherein among the multiple layers of coil structures in the inductor, a coil structure closest to the dielectric substrate is a first coil structure; and
forming the first conductive pattern on the dielectric substrate comprises:
forming a first conductive pattern comprising the first plate and the first coil structure on the dielectric substrate.

17. The method for preparing a filter according to claim 16, wherein the first plate and the first coil structure are integrally formed; wherein after forming the second conductive pattern, the method further comprises:
forming a third interlayer insulation layer on a side of the second conductive pattern facing away from the first conductive pattern; and the third interlayer insulation layer covers the second plate, and the first plate and the first coil structure integrally formed.

18. The method for preparing a filter according to claim 16, wherein the first plate and the first coil structure are integrally formed; and
forming the first conductive pattern comprising the first plate and the first coil structure on the dielectric substrate comprises:
forming a fourth interlayer insulation layer on the dielectric substrate, wherein the fourth interlayer insulation layer comprises a first receiving portion running through the fourth interlayer insulation layer in a thickness direction of the fourth interlayer insulation layer; and
filling the first plate and the first coil structure integrally formed in the first receiving portion to form the first conductive pattern, wherein a surface of the first plate and the first coil structure integrally formed facing away from the dielectric substrate is flush with a surface of the fourth interlayer insulation layer facing away from the dielectric substrate.

19. The method for preparing a filter according to claim 18, wherein after forming the second conductive pattern, the method further comprises:
forming a fifth interlayer insulation layer on a side of the second conductive pattern facing away from the first conductive pattern, wherein a surface of the fifth interlayer insulation layer facing away from the dielectric substrate is parallel to a reference plane of the dielectric substrate extending in a first direction.

20. The method for preparing a filter according to claim 14, wherein forming any one layer of the third conductive patterns comprises:
forming a seventh interlayer insulation layer on the dielectric substrate with the second conductive pattern, wherein the seventh interlayer insulation layer comprises a second receiving portion running through the seventh interlayer insulation layer in a thickness direction of the seventh interlayer insulation layer; and
filling a coil structure material of the inductor in the second receiving portion to form the third conductive pattern, wherein a surface of the third conductive pattern facing away from the dielectric substrate is flush with a surface of the seventh interlayer insulation layer facing away from the dielectric substrate.

21. The method for preparing a filter according to claim 14, wherein forming any one layer of the third conductive patterns comprises:
forming, through electroplating, the third conductive pattern comprising the coil structure on a side of the first interlayer insulation layer facing away from the dielectric substrate.

22. (canceled)

23. An electronic apparatus, comprising the filter according to claim 1.
